(19) United States
(12) Patent Application Publication
(10) Pub. No.: US 2026/0052715 A1
(43) Pub. Date: Feb. 19, 2026

(54) NANOWIRE FIELD EFFECT TRANSISTOR AND METHODS FOR FORMING THE SAME

(71) Applicant: Taiwan Semiconductor Manufacturing Company Limited, Hsinchu (TW)

(72) Inventors: Yu-Cheng SHIAU, Hsinchu (TW); Wei LIU, Kaohsiung City (TW); Cheng-Wei CHANG, Hsinchu (TW); Chao-Hui LIU, Hsinchu (TW); Yu-Ting CIOU, Hsinchu City (TW); Chih-Tang PENG, Zhubei City (TW); Tai-Chun HUANG, Hsinchu City (TW); Tze-Liang LEE, Hsinchu (TW)

(21) Appl. No.: 18/801,880

(22) Filed: Aug. 13, 2024

(51) Int. Cl. H01L 29/66; H01L 29/06; H01L 29/423; H01L 29/775; H01L 29/786

(52) U.S. Cl. CPC H10D 30/014; H10D 30/43; H10D 30/6735; H10D 30/6757; H10D 62/121; H10D 64/017

(57) ABSTRACT

A semiconductor structure may be formed by: forming semiconductor nanowires over a substrate, wherein the semiconductor nanowires and the substrate are vertically spaced from one another by gaps, and wherein the semiconductor nanowires are suspended over the substrate by a support structure; performing at least two iterations of a sequence of processing steps that includes a flowable chemical vapor deposition process that deposits a respective dielectric material and an ultraviolet cure process that irradiates ultraviolet radiation to the respective dielectric material; and forming dielectric spacer structures having a lesser lateral extent than the semiconductor nanowires by isotropically etching the dielectric materials deposited by instances of the flowable chemical vapor deposition process and densified by instances of the ultraviolet cure process.

### BACKGROUND

Transistor, such as gate-all-around (GAA) transistors provide high device current density per device area by vertically stacking semiconductor nanowires. Further, gate-all-around transistors provide high on-off current ratios by enhancing control of semiconductor channels.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are various views of an exemplary structure after formation of an alternating stack of sacrificial material layers and semiconductor material layers according to an embodiment of the present disclosure. FIG. 1A is a top-down view. FIG. 1B is a vertical cross-sectional view along the vertical plane B-B′ in FIG. 1A.

FIGS. 2A, 2B, and 2C are various views of the exemplary structure after the formation of a vertically alternating sequence of semiconductor nanowires and sacrificial nanowires according to an embodiment of the present disclosure. FIG. 2A is a top-down view. FIG. 2B is a vertical cross-sectional view along the vertical plane B-B′ in FIG. 2A. FIG. 2C is a vertical cross-sectional view along the vertical plane C-C′ in FIG. 2A.

FIGS. 3A, 3B, and 3C are various views of the exemplary structure after formation of a shallow trench isolation structure according to an embodiment of the present disclosure. FIG. 3A is a top-down view. FIG. 3B is a vertical cross-sectional view along the vertical plane B-B′ in FIG. 3A. FIG. 3C is a vertical cross-sectional view along the vertical plane C-C′ in FIG. 3A.

FIGS. 4A, 4B, 4C, and 4D are various views of the exemplary structure after formation of sacrificial gate structures according to an embodiment of the present disclosure. FIG. 4A is a top-down view. FIG. 4B is a vertical cross-sectional view along the vertical plane B-B′ in FIG. 4A. FIG. 4C is a vertical cross-sectional view along the vertical plane C-C′ in FIG. 4A. FIG. 4D is a vertical cross-sectional view along the vertical plane D-D′ in FIG. 4A.

FIGS. 5A, 5B, 5C, and 5D are various views of the exemplary structure after formation of dielectric gate spacers according to an embodiment of the present disclosure. FIG. 5A is a top-down view. FIG. 5B is a vertical cross-sectional view along the vertical plane B-B′ in FIG. 5A. FIG. 5C is a vertical cross-sectional view along the vertical plane C-C′ in FIG. 5A. FIG. 5D is a vertical cross-sectional view along the vertical plane D-D′ in FIG. 5A.

FIGS. 6A, 6B, 6C, and 6D are various views of the exemplary structure after cutting the vertically alternating sequence of semiconductor nanowires and sacrificial nanowires into a plurality of vertically alternating sequences of semiconductor nanowires and sacrificial nanowires according to an embodiment of the present disclosure. FIG. 6A is a top-down view. FIG. 6B is a vertical cross-sectional view along the vertical plane B-B′ in FIG. 6A. FIG. 6C is a vertical cross-sectional view along the vertical plane C-C′ in FIG. 6A. FIG. 6D is a vertical cross-sectional view along the vertical plane D-D′ in FIG. 6A.

FIGS. 7A, 7B, 7C, 7D, and 7E are various views of the exemplary structure after removal of the sacrificial nanowires according to an embodiment of the present disclosure. FIG. 7A is a top-down view. FIG. 7B is a vertical cross-sectional view along the vertical plane B-B′ in FIG. 7A. FIG. 7C is a vertical cross-sectional view along the vertical plane C-C′ in FIG. 7A. FIG. 7D is a vertical cross-sectional view along the vertical plane D-D′ in FIG. 7A. FIG. 7E is a magnified view of a region around semiconductor nanowires in FIG. 7B.

FIGS. 8A-8G are sequential vertical cross-sectional views of a region around semiconductor nanowires during formation of dielectric spacer structures and source/drain regions in a first configuration of the exemplary structure according to an embodiment of the present disclosure.

FIGS. 9A-9F are sequential vertical cross-sectional views of a region around semiconductor nanowires during formation of dielectric spacer structures and source/drain regions in a second configuration of the exemplary structure according to an embodiment of the present disclosure.

FIGS. 10A-10E are sequential vertical cross-sectional views of a region around semiconductor nanowires during formation of dielectric spacer structures and source/drain regions in a third configuration of the exemplary structure according to an embodiment of the present disclosure.

FIGS. 11A, 11B, 11C, 11D, and 11E are various views of the exemplary structure after formation of source/drain regions according to an embodiment of the present disclosure. FIG. 11A is a top-down view. FIG. 11B is a vertical cross-sectional view along the vertical plane B-B′ in FIG. 11A. FIG. 11C is a vertical cross-sectional view along the vertical plane C-C′ in FIG. 11A. FIG. 11D is a vertical cross-sectional view along the vertical plane D-D′ in FIG. 11A. FIG. 11E is a magnified view of a region around semiconductor nanowires in FIG. 11B.

FIGS. 12A, 12B, 12C, 12D, and 12E are various views of the exemplary structure after formation of a contact-level dielectric layer according to an embodiment of the present disclosure. FIG. 12A is a top-down view. FIG. 12B is a vertical cross-sectional view along the vertical plane B-B′ in FIG. 12A. FIG. 12C is a vertical cross-sectional view along the vertical plane C-C′ in FIG. 12A. FIG. 12D is a vertical cross-sectional view along the vertical plane D-D′ in FIG. 12A. FIG. 12E is a magnified view of a region around semiconductor nanowires in FIG. 12B.

FIGS. 13A, 13B, 13C, 13D, and 13E are various views of the exemplary structure after formation of gate cavities according to an embodiment of the present disclosure. FIG. 13A is a top-down view. FIG. 13B is a vertical cross-sectional view along the vertical plane B-B′ in FIG. 13A. FIG. 13C is a vertical cross-sectional view along the vertical plane C-C′ in FIG. 13A. FIG. 13D is a vertical cross-sectional view along the vertical plane D-D′ in FIG. 13A. FIG. 13E is a magnified view of a region around semiconductor nanowires in FIG. 13B.

FIGS. 14A, 14B, 14C, 14D, and 14E are various views of the exemplary structure after formation of replacement gate structures according to an embodiment of the present disclosure. FIG. 14A is a top-down view. FIG. 14B is a vertical cross-sectional view along the vertical plane B-B′ in FIG. 14A. FIG. 14C is a vertical cross-sectional view along the vertical plane C-C′ in FIG. 14A. FIG. 14D is a vertical cross-sectional view along the vertical plane D-D′ in FIG. 14A. FIG. 14E is a magnified view of a region around semiconductor nanowires in FIG. 14B.

FIGS. 15A, 15B, 15C, 15D, and 15E are various views of the exemplary structure after formation of contact via structures according to an embodiment of the present disclosure. FIG. 15A is a top-down view. FIG. 15B is a vertical cross-sectional view along the vertical plane B-B′ in FIG. 15A. FIG. 15C is a vertical cross-sectional view along the vertical plane C-C′ in FIG. 15A. FIG. 15D is a vertical cross-sectional view along the vertical plane D-D′ in FIG. 15A. FIG. 15E is a magnified view of a region around semiconductor nanowires in FIG. 15B.

FIG. 16 is a first flowchart illustrating steps for forming a device structure of the present disclosure according to an embodiment of the present disclosure.

FIG. 17 is a second flowchart illustrating steps for forming a device structure of the present disclosure according to an embodiment of the present disclosure.

FIG. 18 is a third flowchart illustrating steps for forming a device structure of the present disclosure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures.

The apparatus may be otherwise oriented (rotated 90 degrees or at other orientations) and the spatially relative descriptors used herein may likewise be interpreted accordingly.

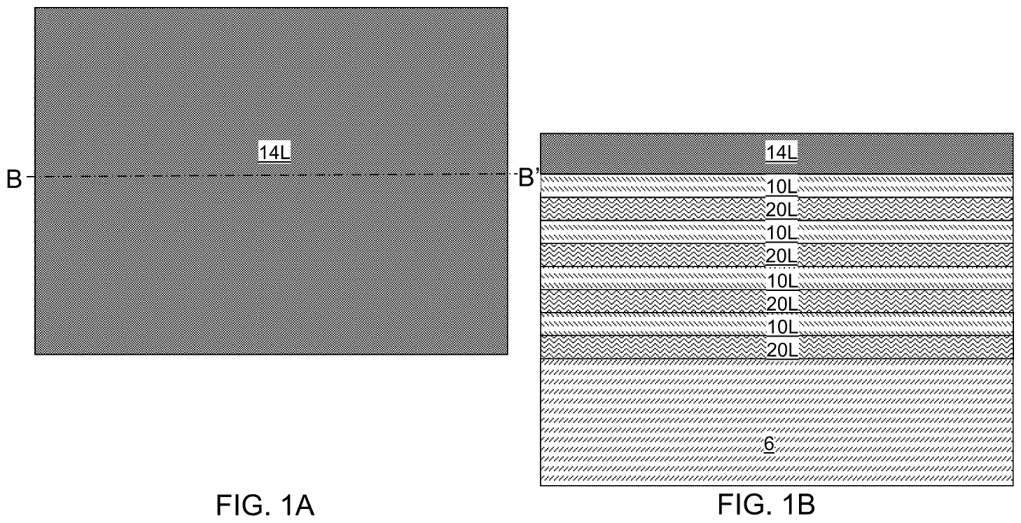

Referring to FIGS. 1A and 1B, an exemplary structure according to an embodiment of the present disclosure is illustrated, which may include a substrate 6 containing a substrate single crystalline semiconductor layer. The substrate single crystalline semiconductor layer may include a semiconductor wafer such as a commercially available single crystalline silicon wafer. In one embodiment, the substrate single crystalline semiconductor layer may comprise a single crystalline semiconductor material layer. The thickness of the substrate 6 may be in a range from 200 microns to 1 mm, although lesser and greater thicknesses may also be used.

An alternating stack of sacrificial material layers 20L and semiconductor material layers 10L may be deposited on the top surface of the substrate single crystalline semiconductor layer by performing epitaxial deposition processes. Each of the sacrificial material layers 20L and the semiconductor material layers 10L may be formed by an epitaxial deposition process in which a single crystalline silicon-germanium alloy material or a single crystalline silicon is deposited with epitaxial registry with underlying single crystalline semiconductor layers, i.e., the substrate single crystalline semiconductor layer and any underlying sacrificial material layer 20L and/or any underlying semiconductor material layer 10L. In one embodiment, the sacrificial material layers 20L may include a respective single crystalline silicon-germanium alloy material including germanium at an atomic concentration in a range from 15 % to 35 %, such as from 20 % to 30 %, although lesser and greater atomic concentrations may also be used. The thickness of each sacrificial material layer 20L may be in a range from 10 nm to 200 nm, such as from 20 nm to 100 nm, although lesser and greater thicknesses may also be used. In one embodiment, the semiconductor material layers 10L may include single crystalline silicon. The thickness of each semiconductor material layer 10L may be in a range from 3 nm to 40 nm, such as from 6 nm to 20 nm, although lesser and greater thicknesses may also be used.

Generally, a vertically interlaced stack of semiconductor material layers 10L and sacrificial material layers 20L may be grown on a single crystalline semiconductor material of a substrate 6. Each semiconductor material layer 10L and each sacrificial material layer 20L may be single crystalline, and may be epitaxially aligned among one another. Thus, each crystallographic orientation having a same Miller index may be orientated along a same direction within each of the semiconductor material layers 10L, the sacrificial material layers 20L, and the substrate single crystalline semiconductor layer.

In one embodiment, the semiconductor material layers 10L may be single crystalline silicon layers. The atomic concentration of electrical dopants in each of the semiconductor material layers 10L may be in a range from 1.0×10¹⁴/cm³ to 1.0×10¹⁷/cm³, although lesser and greater dopant concentrations may also be used. In some embodiments, the exemplary structure may comprise multiple device regions in which the semiconductor material layers 10L are doped with electrical dopants at different atomic concentrations or with dopants of different conductivity types. The total number of pairs of a sacrificial material layer 20L and a semiconductor material layer 10L within the alternating stack of the sacrificial material layers 20L and the semiconductor material layers may be in a range from 2 to 20, such as from 3 to 6, although a greater number may also be used.

A hardmask material layer 14L may be deposited over the alternating stack of sacrificial material layers 20L and semiconductor material layers 10L. The hardmask material layer 14L comprises a hardmask material such as silicon nitride. The thickness of the hardmask material layer 14L may be in a range from 30 nm to 100 nm, although lesser and greater thicknesses may also be used.

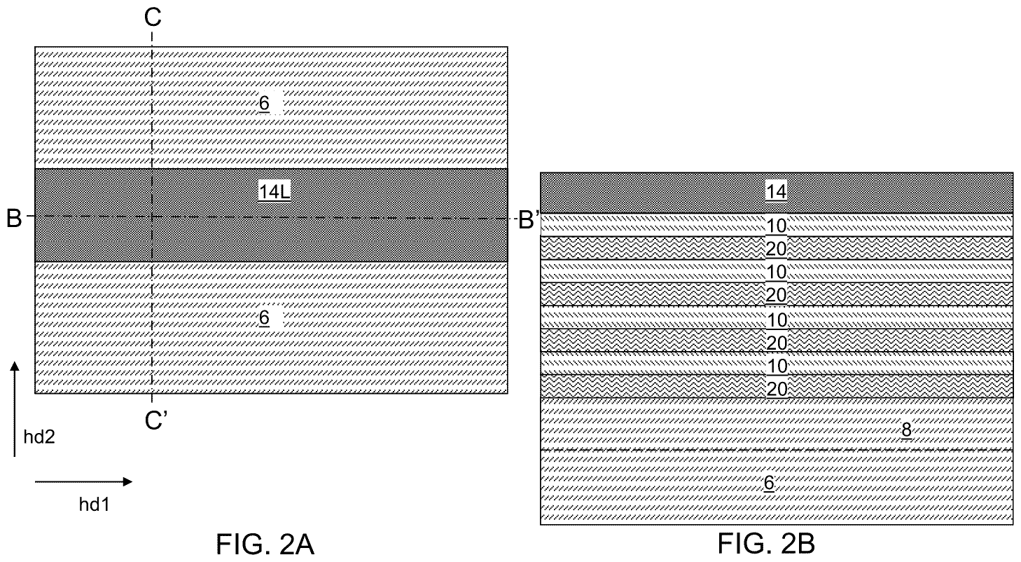

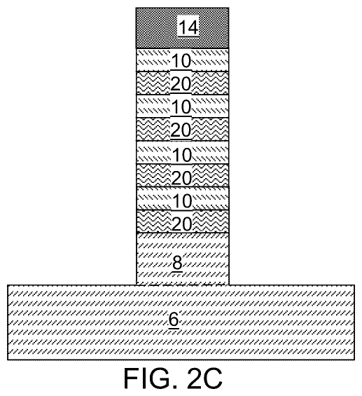

Referring to FIGS. 2A-2C, a photoresist layer (not shown) may be applied over the hardmask material layer 14L, and may be lithographically patterned to form a line and space pattern that laterally extends along a first horizontal direction hd1 and laterally spaced apart along a second horizontal direction hd2 that is perpendicular to the first horizontal direction hd1. An anisotropic etch process may be performed to transfer the pattern in the photoresist layer through the hardmask material layer 14L. The hardmask material layer 14L may be patterned into hardmask plates 14. The photoresist layer may be subsequently removed, for example, by ashing.

An anisotropic etch process may be performed to transfer the pattern of the hardmask plates 14 through the alternating stack of sacrificial material layers 20L and semiconductor material layers 10L and into a top portion of the substrate single crystalline semiconductor layer Nanowire stack structures including patterned portions of the underlying material layers (10L, 20L) and the top portion of the substrate single crystalline semiconductor layer 10 may be formed underneath the hardmask plates 14.

Each nanowire stack structure may include, from bottom to top, a single crystalline semiconductor fin 8 that may be a patterned top portion of the substrate single crystalline semiconductor layer, and a nanowire stack (10, 20) that is an alternating stack of sacrificial nanowires 20 and semiconductor nanowires 10, an optional silicon oxide liner (not shown). In one embodiment, each single crystalline semiconductor fin 8 may be a single crystalline silicon fin. Each semiconductor nanowire 10 is a patterned portion of a semiconductor material layer 10L. Each sacrificial nanowire 20 is a patterned portion of a sacrificial material layer 20L. As used herein, a “nanowire” refers to a structure that extends along a lengthwise direction and has nanoscale widthwise dimensions. Each widthwise dimension of a nanowire may be in a range from 1 nm to 999 nm, such as from 4 nm to 100 nm.

In one embodiment, each nanowire stack structure (8, 10, 20) may have a uniform width, which may be in a range from 10 nm to 300 nm, such as from 20 nm to 150 nm, although lesser and greater widths may also be used. In one embodiment, the spacing between neighboring nanowire stack structures (8, 10, 20) may be in a range from 50 nm to 250 nm, although lesser and greater thicknesses may also be used. Each nanowire stack structure (8, 10, 20) may laterally extend along the first horizontal direction hd1, and may be laterally spaced apart from another nanowire stack structure (8, 10, 20) along the second horizontal direction hd2. While the illustrated portion of the exemplary structure includes a single nanowire stack structure (8, 10, 20), it is understood that a plurality of nanowire stack structures (8, 10, 20) may be provided in the exemplary structure.

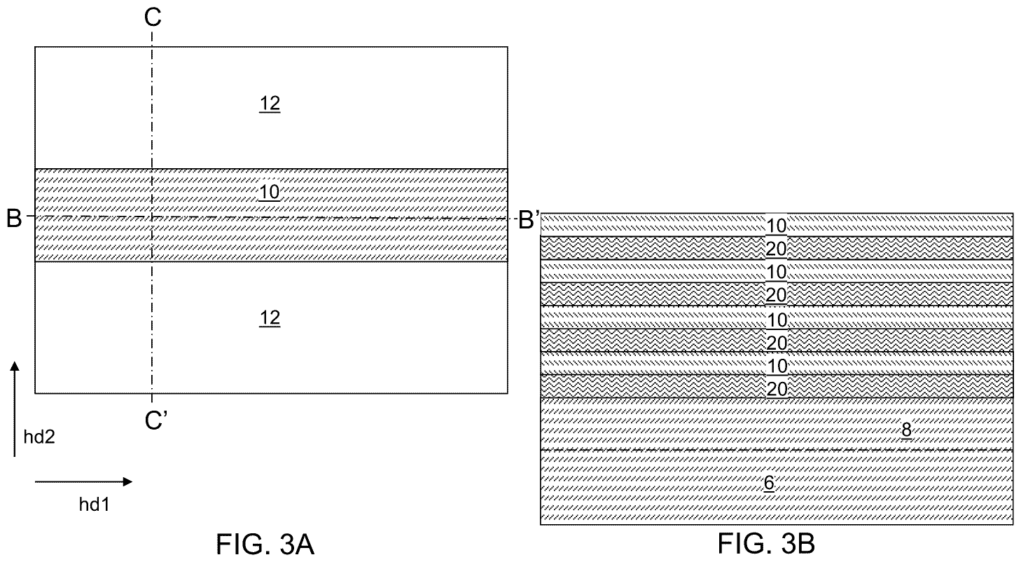

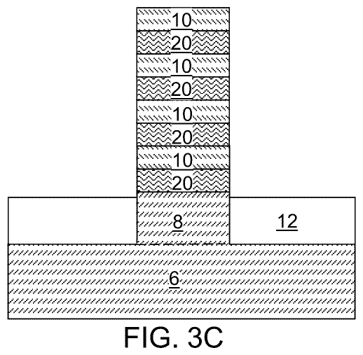

Referring to FIGS. 3A-3C, a dielectric fill material such as silicon oxide may be deposited in the trenches between neighboring pairs of the nanowire stack structures (8, 10, 20). A planarization process such as a chemical mechanical planarization process may be performed to remove portions of the dielectric fill material located above the horizontal plane including the top surfaces of the hardmask plates 14. Remaining portions of the dielectric fill material comprise shallow trench isolation structures 12.

Top surfaces of the shallow trench isolation structures 12 may be vertically recessed by performing a recess etch process that etches the dielectric material of the shallow trench isolation structures 12 selective to the hardmask plates 14. The recess etch process may use an isotropic etch process (such as a wet etch process) or an anisotropic etch process (such as a reactive ion etch process). In embodiments in which a reactive ion etch process is used to etch back the shallow trench isolation structures 12, the hardmask plates 14 may be used as etch mask structures. In embodiments in which a wet etch process is used to etch back the shallow trench isolation structures 12, the chemistry of the wet etch process may be selected to etch the material of the shallow trench isolation structures 12 selective to the materials of the hardmask plates 14 and the nanowire stack structures (8, 10, 20).

The top surfaces of the shallow trench isolation structures 12 may be recessed such that the top surfaces of the shallow trench isolation structures 12 are at, or about, the interfaces between the bottommost sacrificial nanowires 20 and the single crystalline semiconductor fins 8. The hardmask plates 14 may be subsequently removed selective to the shallow trench isolation structures 12 and the nanowire stack structures (8, 10, 20). For example, if the hardmask plates 14 comprise silicon nitride, a wet etch process using hot phosphoric acid may be used to remove the hardmask plates 14.

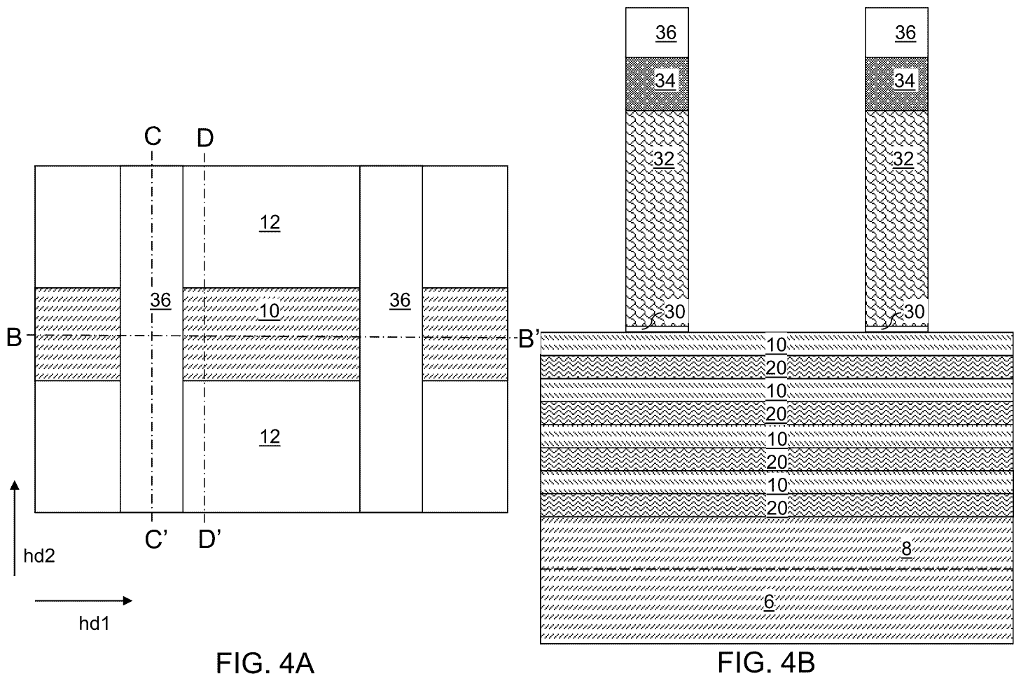

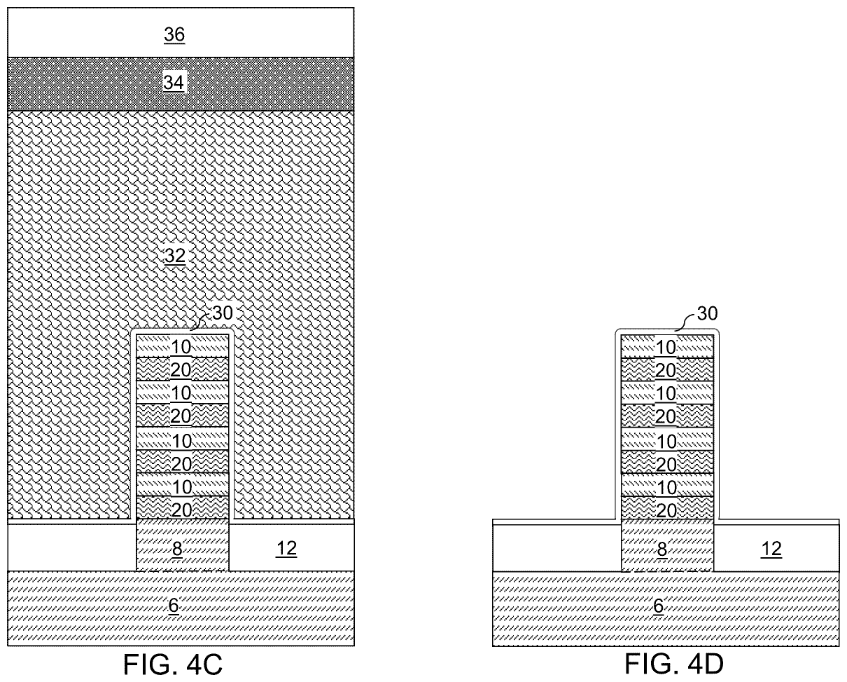

Referring to FIGS. 4A-4D, sacrificial gate structures (30, 32, 34, 36) may be formed by depositing and patterning a sacrificial dielectric liner layer, a sacrificial gate electrode material layer, and at least one gate hardmask material layer. The sacrificial dielectric liner layer may comprise a sacrificial dielectric material such as silicon oxide, silicon oxynitride, silicon nitride, or a dielectric metal oxide, and may be formed by a conformal deposition process such as a chemical vapor deposition process or an atomic layer deposition process. The thickness of the sacrificial dielectric liner layer may be in a range from 1 nm to 6 nm, although lesser and greater thicknesses may also be used.

The sacrificial gate electrode material layer may comprise a silicon-germanium alloy including germanium at an atomic concentration in a range from 25 % to 50 %, such as from 35 % to 45 %, although lesser and greater thicknesses may also be used. The thickness of the sacrificial gate electrode material layer may be greater than the height of the nanowire stacks (10, 20). In one embodiment, the top surface of the sacrificial electrode material layer may be planarized by performing a chemical mechanical polishing process. The vertical distance between the planarized top surface of the sacrificial electrode material layer and the top surfaces of the nanowire stacks (10, 20) may be in a range from 20 nm to 300 nm, such as from 60 nm to 150 nm, although lesser and greater vertical distances may also be used. The at least one gate hardmask material layer comprises at least one hardmask material such as a stack of a silicon nitride material and a silicon oxide material.

A photoresist layer (not shown) may be applied over the at least one gate hardmask material layer, and may be lithographically patterned into a gate pattern. In one embodiment, the gate pattern may comprise a plurality of line patterns each laterally extending along the second horizontal direction hd2. An anisotropic etch process may be performed to transfer the pattern in the photoresist layer through the at least one gate hardmask material layer. The at least one gate hardmask material layer may be patterned into gate hardmask strips (34, 36). In one embodiment, the at least one gate hardmask material layer may comprise a layer stack of a first gate hardmask material layer and a second gate hardmask material layer, and each gate hardmask strip (34, 36) may comprise a vertical stack of a first gate hardmask portion 34 and a second gate hardmask portion 36. In one embodiment, the first gate hardmask portions 34 may comprise a first hardmask material such as silicon nitride, and the second gate hardmask portions 36 may comprise a second hardmask material such as silicon oxide. The photoresist layer may be subsequently removed, for example, by ashing.

An anisotropic etch process may be performed to transfer the pattern of the gate hardmask strips (34, 36) through the sacrificial gate electrode material layer. The anisotropic etch process may comprise a reactive ion etch process that etches the material of the sacrificial gate electrode material layer selective to the material of the sacrificial dielectric liner layer. For example, if the sacrificial gate electrode material layer comprises a silicon-germanium alloy and if the sacrificial dielectric liner layer comprises silicon oxide, a reactive ion etch process that etches the silicon-germanium alloy selective to silicon oxide may be used. Each patterned portion of the sacrificial gate electrode material layer comprises a sacrificial gate electrode 32.

The sacrificial dielectric liner layer may be subsequently patterned using the gate hardmask strips (34, 36) as an etch mask. The sacrificial dielectric liner layer may be patterned into sacrificial dielectric liners 30. Each sacrificial gate structure (30, 32, 34, 36) may comprise a stack of a sacrificial dielectric liner 30, a sacrificial gate electrode 32, and a gate hardmask strip (34, 36). Each sacrificial gate structure (30, 32, 34, 36) straddles a respective nanowire stack (10, 20), and may have a uniform thickness along the first horizontal direction hd1, which is herein referred to as a gate length. The gate length may be in a range from 3 nm to 100 nm, such as from 6 nm to 40 nm, although lesser and greater gate lengths may also be used. Generally, at least one sacrificial gate electrode 32 may be formed over each vertically alternating sequence (10, 20) of the semiconductor nanowires 10 and sacrificial nanowires 20. In one embodiment, the semiconductor nanowires 10 comprise portions of a single crystalline semiconductor material.

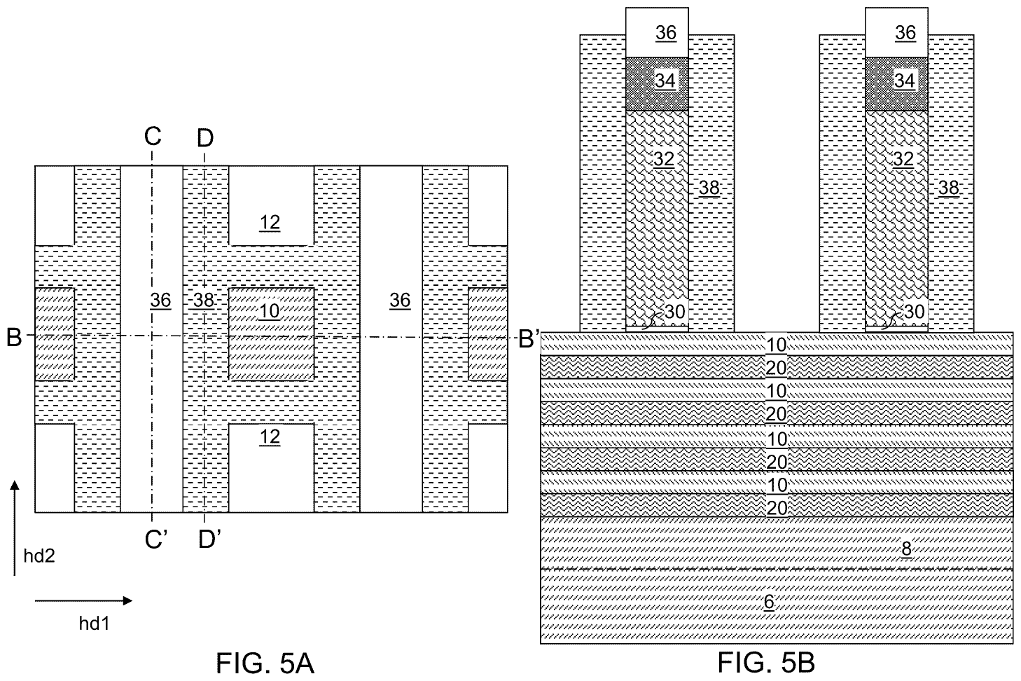

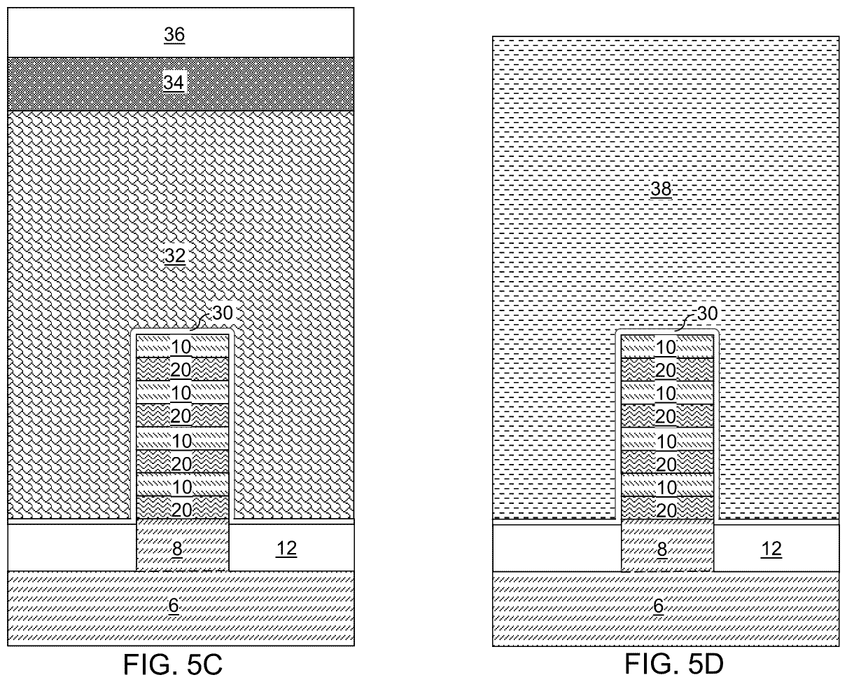

Referring to FIGS. 5A-5D, a gate spacer dielectric material may be conformally deposited and may be subsequently anisotropically etched by performing a reactive ion etch process. The gate spacer dielectric material may comprise silicon oxynitride, silicon oxycarbide, silicon carbonitride, or silicon nitride. Generally, the gate spacer dielectric material may have a material composition that is different from silicon oxide. The gate spacer dielectric material may be deposited by a conformal deposition process such as a chemical vapor deposition process.

A first anisotropic etch process may be performed to etch horizontally-extending portions of the gate spacer dielectric material selective to the material of the semiconductor nanowires and preferably selective to the material of the shallow trench isolation structures 12. Remaining portions of the gate spacer dielectric material comprise dielectric gate spacers 38. The lateral thickness of the dielectric gate spacers 38 may be in a range from 5 nm to 200 nm, such as from 10 nm to 100 nm, although lesser and greater thicknesses may also be used.

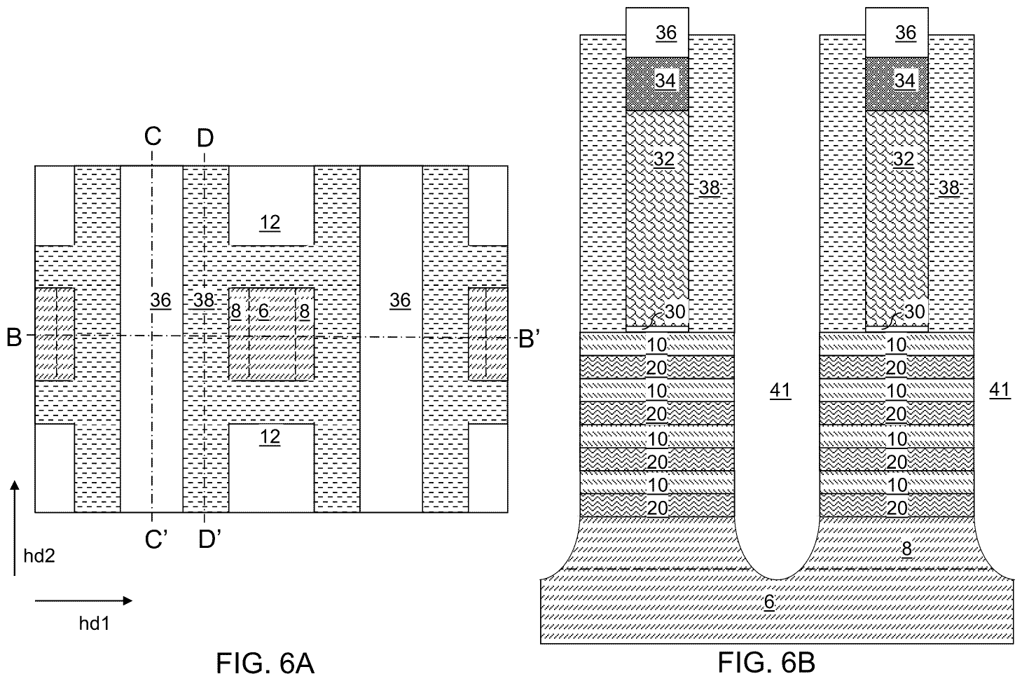

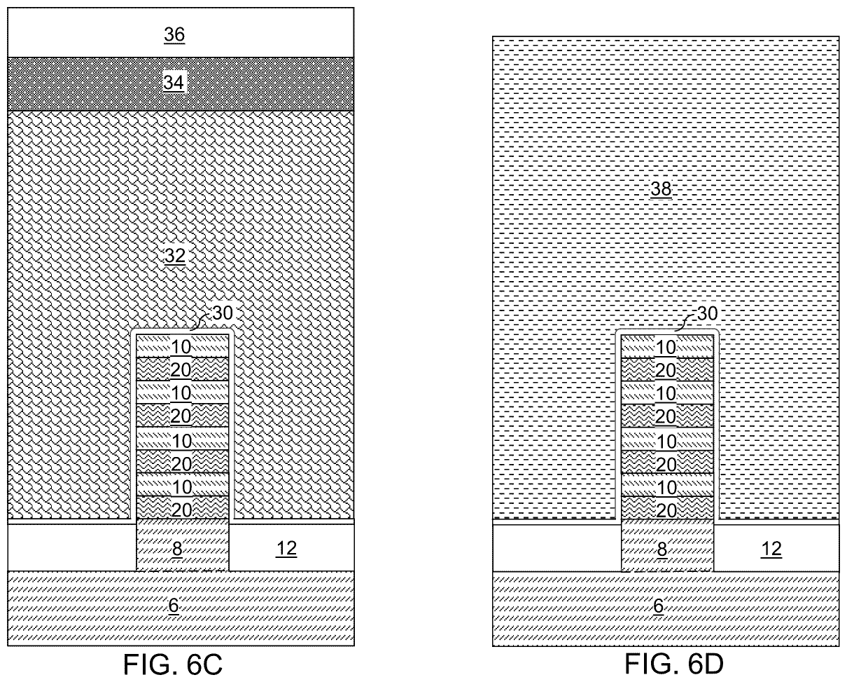

Referring to FIGS. 6A-6D, a second anisotropic etch process may be performed to etch portions of the nanowire stack structures (8, 10, 20) that are not masked by the sacrificial gate structures (30, 32, 34, 36) or the dielectric gate spacers 38. Each nanowire stack structures (8, 10, 20) may be divided into a respective plurality of nanowire stack structures (8, 10, 20) that are laterally spaced apart among one another along the first horizontal direction hd1. Separation trenches 41 may be formed in the volumes from which the materials of the nanowire stack structures (8, 10, 20) are removed.

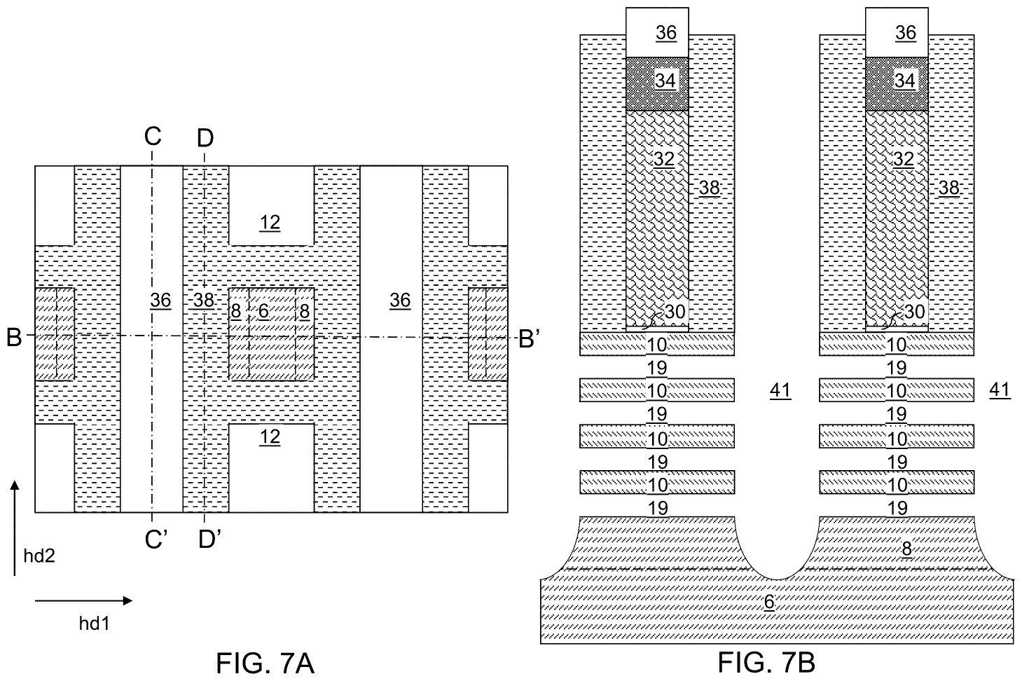

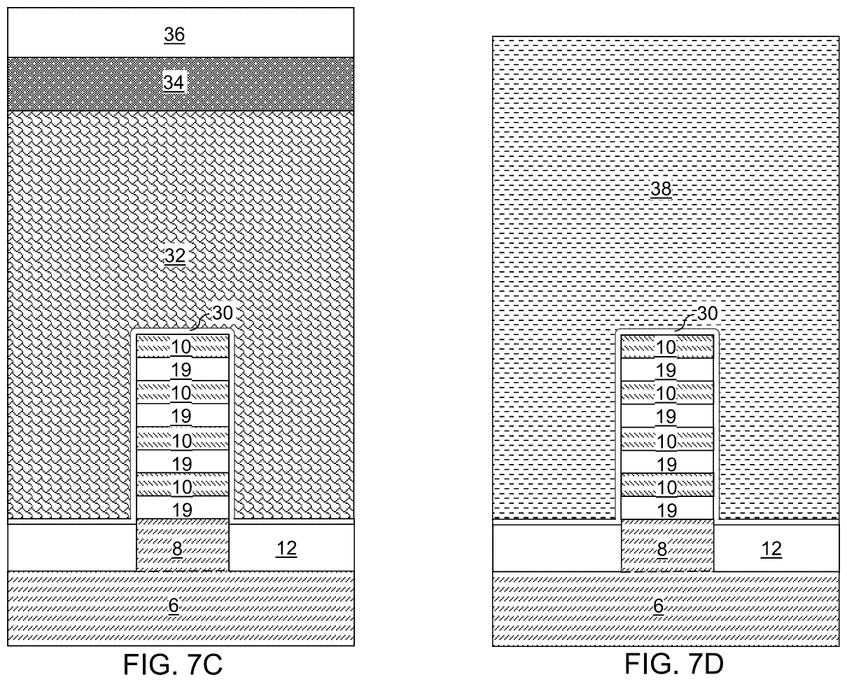

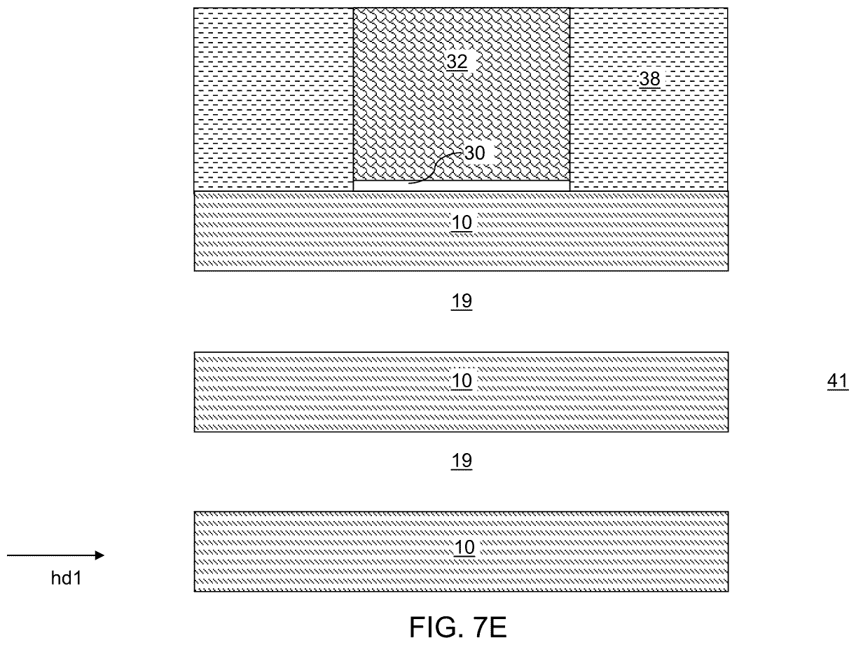

Referring to FIGS. 7A-7E, a selective isotropic etch process may be performed to remove the materials of sacrificial nanowires 20 selective to the materials of the semiconductor nanowires 10, the single crystalline semiconductor fins 8, and the dielectric gate spacers 38. For example, in embodiments in which the semiconductor nanowires 10 comprise single crystalline silicon and in embodiments in which the sacrificial nanowires 20 comprises a single crystalline silicon-germanium alloy, a wet etch process using a mixture of nitric acid, acetic acid, hydrofluoric acid, and deionized water may be used to etch the sacrificial nanowires 20 selective to the semiconductor nanowires 10. According to an aspect of the present disclosure, the sacrificial nanowires 20 may be completely removed. The semiconductor nanowires 10 may be supported by the sacrificial gate structures (30, 32, 34, 36).

The entirety of the sacrificial nanowires 20 may be removed selective to the semiconductor nanowires 10 to form gaps 19 (e.g., voids) in volumes from which the sacrificial nanowires 20 are removed. The gaps 19 may be formed between vertically neighboring pairs of semiconductor nanowires 10 and between neighboring pairs of a semiconductor nanowire 10 and a single crystalline semiconductor fin 8. Generally, the semiconductor nanowires 10 and the substrate 6 may be vertically spaced among one another by the gaps 19, and the semiconductor nanowires 10 are suspended over the substrate 6 by a respective support structure, which may be a respective sacrificial gate structures (30, 32, 34, 36) including a respective sacrificial gate electrode 32.

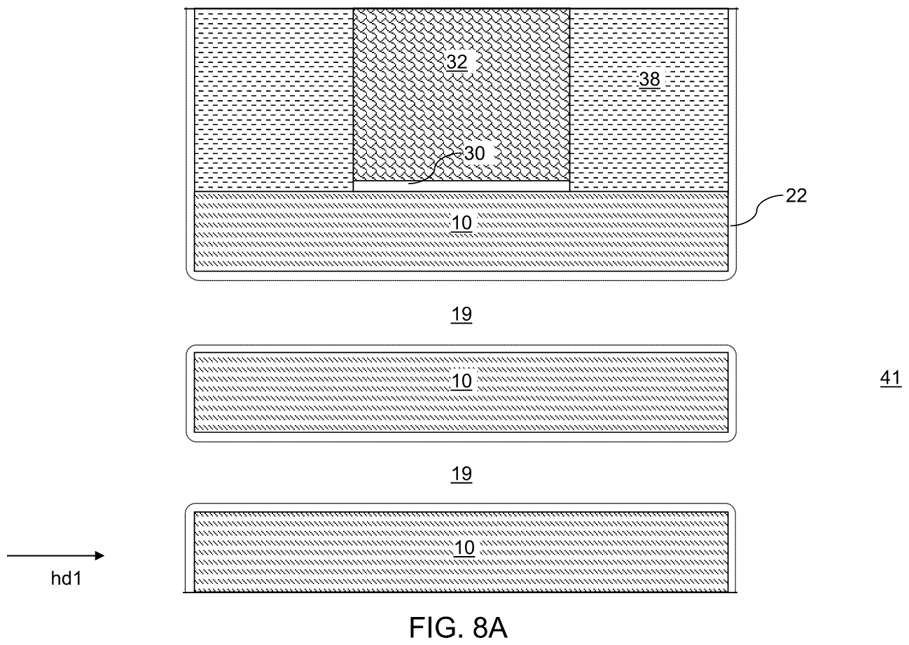

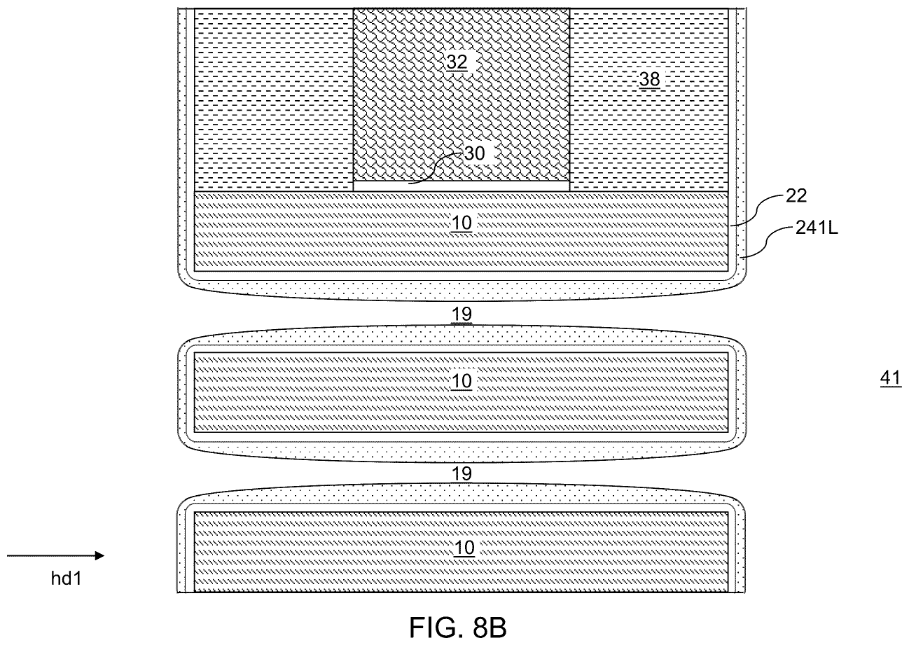

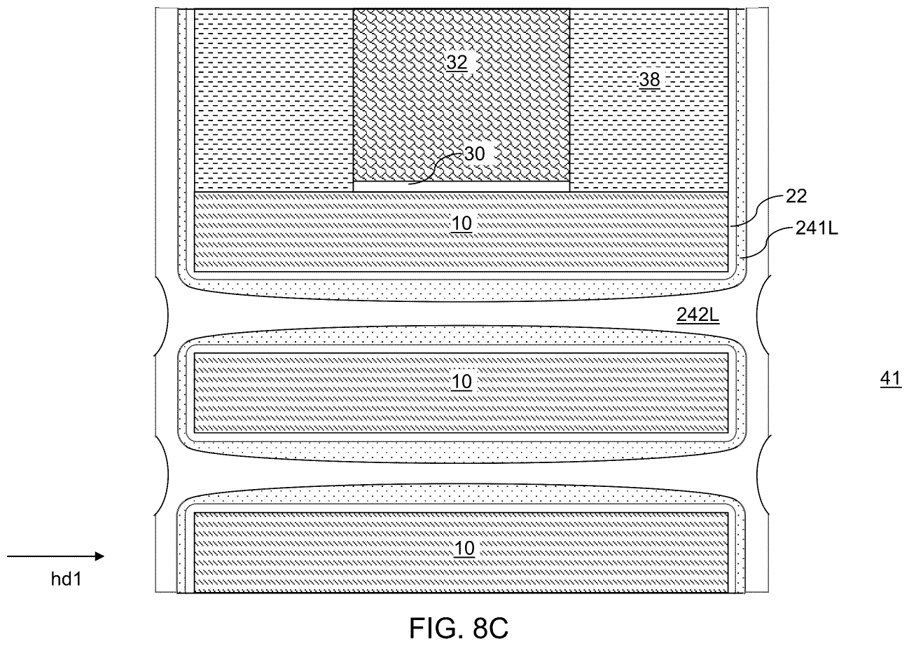

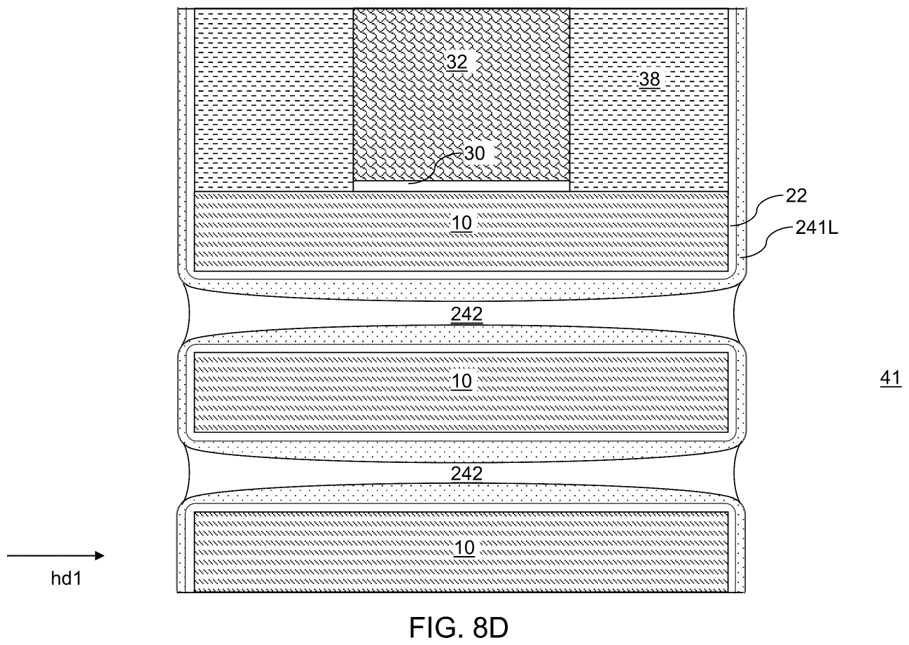

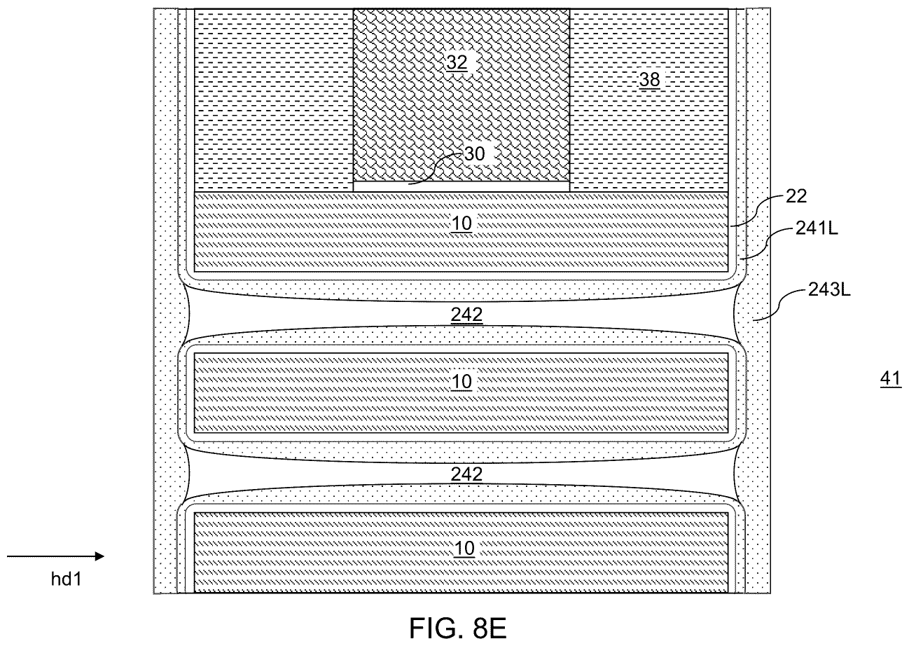

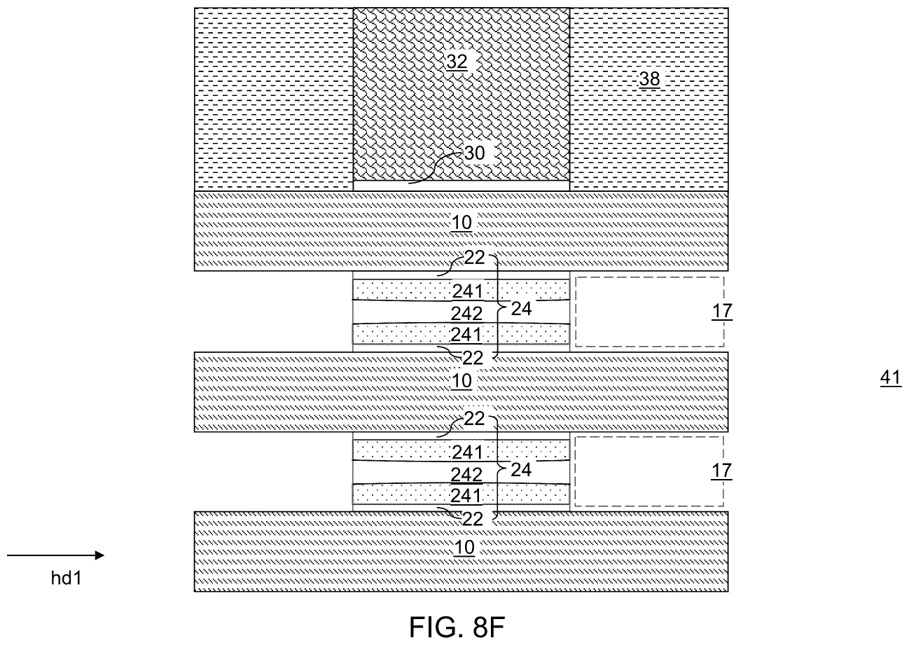

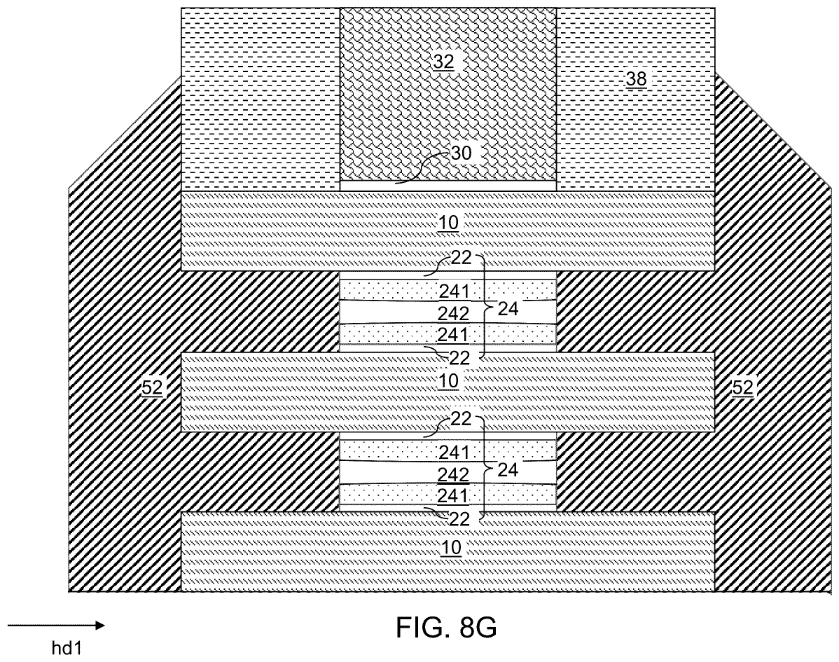

FIGS. 8A-8G are sequential vertical cross-sectional views of a region around semiconductor nanowires 10 during formation of dielectric spacer structures 24 and source/drain regions 52 in a first configuration of the exemplary structure according to an embodiment of the present disclosure.

Referring to FIG. 8A, a conformal dielectric material deposition process may be performed to form a conformal dielectric liner 22 on physically exposed surfaces of the semiconductor nanowires 10. For example, an atomic layer deposition (aLD) process may be performed to conformally deposit a layer of silicon oxide having a uniform thickness throughout. The thickness of the conformal dielectric liner 22 may be in a range from 0.6 nm to 4 nm, such as from 1 nm to 3 nm, although lesser and greater thicknesses may also be used. The conformal dielectric liner 22 may consist essentially of an undoped silicate glass that is free of carbon, i.e., an undoped silicate glass of which an atomic concentration of carbon is below a trace level (e.g., less than 1 part per million).

Referring to FIG. 8B, a first iteration of a sequence of processing steps may be performed, which includes a first instance of a flowable chemical vapor deposition (CVD) process that deposits a first dielectric material and a first instance of an ultraviolet cure process that irradiates ultraviolet radiation to the first dielectric material. In one embodiment, the first flowable chemical vapor deposition process comprises a flowable chemical vapor deposition (FCVD) process that deposits silicon oxide using trisilylamine (TSA) and ammonia (NH₃) as precursor gases. During the FCVD process, TSA and NH3 are introduced into a reaction chamber, and are reacted to deposit a flowable film of hydrogen-rich silicon oxide. In one embodiment, TSA and NH₃ may be alternately flowed into the reaction chamber. Oxygen (O₂) may be flowed into the reaction chamber to assist in the silicon oxide deposition process. The deposited hydrogen-rich film has a low viscosity, and thus, the deposition process is referred to as a flowable chemical vapor deposition (FCVD) process.

In one embodiment, the first instance of the flowable chemical vapor deposition process deposits a first dielectric material on horizontal surfaces of the semiconductor nanowires 10 such that the first dielectric material may have a greater thickness at a center portion of each of the horizontal surfaces of the semiconductor nanowires 10 than peripheral portions of each of the horizontal surfaces of the semiconductor nanowires 10. A first dielectric material layer 241L may be formed. The difference in the thickness of the various portions of the deposited first dielectric material is due to the low viscosity of the deposited hydrogen-containing silicon oxide material, and due to the surface tension of the deposited hydrogen-containing silicon oxide material. Thus, portions of the deposited hydrogen-containing silicon oxide material on center portions of horizontal surface segments of the semiconductor nanowires (which are distal from edges of the horizontal surface segments) may have a greater thickness than portions of the deposited hydrogen-containing silicon oxide material on peripheral portions of the horizontal surface segments. The thickness of the first dielectric material layer 241L at the center portions of the horizontal surfaces of the semiconductor nanowires 10 may be in a range from 105 % to 200 % of the thickness of the first dielectric material layer 241L at the peripheral portions of the horizontal surfaces of the semiconductor nanowires 10.

In one embodiment, each horizontally-extending portion of a first dielectric material layer 241L that is deposited by the first instance of the flowable chemical vapor deposition process has a physically exposed surface after the first instance of the flowable chemical vapor deposition process. In one embodiment, the physically exposed surfaces may have a convex vertical cross-sectional profile in a vertical cross-sectional view along a vertical plane that is parallel to a lengthwise direction of the semiconductor nanowires 10 (such as the vertical cross-sectional view of FIG. 8B). In one embodiment, the first dielectric material layer 241L has a greater thickness on a center portion of a horizontally-extending surface of each of the semiconductor nanowires 10 than on any sidewall of the semiconductor nanowires 10. The gaps 19 are not completely filled by the first dielectric material, and the volume of void within each gap 19 extends between a vertically neighboring pair of horizontally-extending pairs of portions of the first dielectric material layer 241L through the entire length of the semiconductor nanowires 10 along the first horizontal direction hd1.

In one embodiment, the first dielectric material layer 241L may have a material composition of SiOₓN_{y}H_{z}. The atomic percentage of silicon atoms in the first dielectric material layer 241L may be in a range from 20 % to 40 %, the atomic percentage of nitrogen atoms in the first dielectric material layer 241L may be in a range from 1 % to 10 %, and the atomic percentage of oxygen atoms in the first dielectric material layer 241L may be in a range from 40 % to 70 %. The atomic percentage of hydrogen atoms in the first dielectric material layer 241L may be in a range from 1 % to 20 %, such as from 2 % to 10 %. The first dielectric material layer 241L may be substantially free of carbon atoms.

The first instance of the ultraviolet cure process may use ultraviolet irradiation to induce densification of the deposited first dielectric material. Specifically, the ultraviolet radiation breaks S—H bonds and S—OH bonds in the first dielectric material, and induces formation of Si—O—Si bonds. Cross-linking among the silicon atoms and the oxygen atoms in the first dielectric material of the first dielectric material layer 241L increases upon irradiation of the ultraviolet radiation, and the atomic percentage of the hydrogen atoms in the first dielectric material decreases during the first instance of the ultraviolet cure process. This cross-linking process transforms the initially flowable film into a denser, more mechanically stable silicon oxide layer having a higher viscosity (i.e., a higher resistance to flow). Generally, the first instance of the ultraviolet cure process removes volatile organic components and byproducts from the first dielectric material layer 241L, thereby increasing the density and hardness of the first dielectric material layer 241L.

The combination of the flowable chemical vapor deposition process and the ultraviolet cure process provides the advantage of forming the first dielectric material layer 241L with an inversely non-conformal thickness profile, in which the thickness of the first dielectric material layer 241L is greater at locations that are distal from the separation trenches 41. The inversely non-conformal thickness profile of the first dielectric material layer 241L facilitates complete filling of the volumes of the gaps 19 within dielectric materials in combination with at least one subsequently dielectric material deposition process.

Referring to FIG. 8C, a second iteration of the sequence of processing steps may be performed, which includes a second instance of the flowable chemical vapor deposition process that deposits a second dielectric material and a second instance of the ultraviolet cure process that irradiates ultraviolet radiation to the second dielectric material. In one embodiment, the second flowable chemical vapor deposition process may use the same set of process gases and may have the same set, or a similar set, of process parameters as the first flowable chemical vapor deposition process except an optional difference in the duration of the deposition process.

In one embodiment, the second instance of the flowable chemical vapor deposition process deposits a second dielectric material on the surfaces of the first dielectric material layer 241L such that the entire volumes of the gaps 19 are filled within the combination of the conformal dielectric liner 22, the first dielectric material layer 241L, and the second dielectric material layer 242L. The material composition of the second dielectric material layer 242L may be the same as, or may be substantially the same as, the material composition of the first dielectric material layer 241L prior to the first instance of the ultraviolet cure process.

In one embodiment, the second dielectric material layer 242L may comprise contoured vertically-extending surfaces that vertically extend continuously from a horizontal plane including bottommost surfaces of the semiconductor nanowires 10 to a horizontal plane including topmost surfaces of the semiconductor nanowires 10. In one embodiment, each of the contoured vertically-extending surfaces may comprise planar vertical surface segments at levels of the semiconductor nanowires 10 and concave surface segments at levels of the gaps 19. As used herein, a “planar” surface refers to a surface that may be contained within a Euclidean plane.

The second instance of the ultraviolet cure process uses ultraviolet irradiation to induce densification of the deposited second dielectric material. The mechanism of the densification process may be the same as the first instance of the ultraviolet cure process. Generally, the second instance of the ultraviolet cure process removes volatile organic components and byproducts from the second dielectric material layer 242L, thereby increasing the density and hardness of the second dielectric material layer 242L.

Referring to FIG. 8D, an isotropic recess process may be performed to isotropically recess physically exposed surface portions of the second dielectric material layer 242L. The duration of the isotropic recess process may be selected such that the second dielectric material layer 242L is removed from the vertically-extending sidewalls of the first dielectric material layer 241L. The second dielectric material layer 242L may be divided into a plurality of second dielectric material portions 242 that are vertically spaced apart among one another. In one embodiment, each second dielectric material portion 242 may comprise a respective pair of contoured vertically-extending surfaces. In one embodiment, each of the contoured vertically-extending surfaces may comprise, and/or may consist of, a concave surface segments at a level of a gap 19.

Referring to FIG. 8E, a third iteration of the sequence of processing steps may be performed, which includes a third instance of the flowable chemical vapor deposition process that deposits a third dielectric material and a third instance of the ultraviolet cure process that irradiates ultraviolet radiation to the third dielectric material. In one embodiment, the third flowable chemical vapor deposition process may use the same set of process gases and may have the same set, or a similar set, of process parameters as the first flowable chemical vapor deposition process except an optional difference in the duration of the deposition process.

In one embodiment, the third instance of the flowable chemical vapor deposition process deposits a third dielectric material on the surfaces of the first dielectric material layer 241L and the second dielectric material portions 242 until planar vertically-extending surface of the third dielectric material is formed. A third dielectric material layer 243L having planar vertical surfaces may be formed. The low viscosity of the third dielectric material causes reflow of the deposited third dielectric material during the deposition process, and thus, induces filling of the concave voids overlying the second dielectric material portions 242. The material composition of the third dielectric material layer 243L may be the same as, or may be substantially the same as, the material composition of the first dielectric material layer 241L prior to the first instance of the ultraviolet cure process.

Generally, at least two iterations of a sequence of processing steps may be performed. The sequence of processing steps includes a flowable chemical vapor deposition process that deposits a respective dielectric material and an ultraviolet cure process that irradiates ultraviolet radiation to the respective dielectric material. During formation of the first configuration of the exemplary structure, the at least two iterations of the sequence comprises a third iteration of the sequence that includes a third instance of the flowable chemical vapor deposition process and a third instance of the ultraviolet cure process. In this embodiment, a third dielectric material (comprising the third dielectric material layer 243L) is deposited by the third instance of the flowable chemical vapor deposition process, and is cured by the third instance of the ultraviolet cure process. The third dielectric material layer 243L comprises a pair of planar vertically-extending surfaces. Each planar vertically-extending surface of the third dielectric material layer 243L vertically extends continuously through each level of the semiconductor nanowires 10 and through each level of the gaps 19. Generally, the dielectric materials deposited by instances of the flowable chemical vapor deposition process fill an entire volume of each of the gaps 19.

Referring to FIG. 8F, a selective isotropic etch process may be performed to etch the materials of the conformal dielectric liner 22, the first dielectric material layer 241L, the second dielectric material portions 242, and the third dielectric material layer 243L selective to the materials of the semiconductor nanowires 10, the single crystalline semiconductor fins 8, and the dielectric gate spacers 38. In one embodiment, the selective isotropic etch process may comprise a wet etch process using dilute hydrofluoric acid. The selective isotropic etch process may etch the materials of the conformal dielectric liner 22, the first dielectric material layer 241L, the second dielectric material portions 242, and the third dielectric material layer 243L at the same etch rate. The selective isotropic etch process removes the entirety of the third dielectric material layer 243L. The end sidewalls of the semiconductor nanowires 10 that are perpendicular to the first horizontal direction hd1 may be physically exposed.

Remaining portions of the conformal dielectric liner 22, the first dielectric material layer 241L, and the second dielectric material portions 242 comprise dielectric spacer structures 24. Each dielectric spacer structure 24 comprises a pair of conformal dielectric liners 22, a first dielectric material portion 241 (which may be topologically homeomorphic to a torus), and a second dielectric material portion 242. The first dielectric material portion 241 is a remaining portion of the first dielectric material layer 241L. The dielectric spacer structures 24 having a lesser lateral extent than the semiconductor nanowires 10 along the first horizontal direction hd1. In one embodiment, the lateral extent of each dielectric spacer structure 24 may be about the same as the lateral extent of a respective overlying sacrificial gate structure (30, 32, 34, 36). According to an aspect of the present disclosure, each dielectric spacer structure 24 may have a pair of vertical planar sidewalls that are perpendicular to the first horizontal direction hd1. Inter-nanowire cavities 17 may be formed in the voids that are formed within the volumes of the gaps 19 as provided at the processing steps of FIGS. 7A-7E. According to an aspect of the present disclosure, each inter-nanowire cavity 17 may have a volume of a respective rectangular parallelopiped.

Referring to FIG. 8G, a selective semiconductor deposition process may be performed to grow a heavily doped semiconductor material from the physically exposed semiconductor surfaces of the semiconductor nanowires 10 and the single crystalline semiconductor fins 8 while suppressing growth of the heavily doped semiconductor material from dielectric surfaces. Specifically, the selective semiconductor deposition process grows the heavily doped semiconductor material from physically exposed surfaces of the semiconductor nanowires 10 while suppressing growth of the semiconductor material from surfaces of the of the dielectric spacer structures 24 and the dielectric gate spacers 38. The heavily doped semiconductor material forms source/drain regions 52 in the separation trenches 41. As used herein, a “source/drain region” may be a source region or a drain region. The atomic concentration of electrical dopants in the source/drain regions 52 may be in a range from 5.0×10¹⁹/cm³ to 2.0×10²¹/cm³, although lesser and greater atomic concentrations may also be used.

Generally, the source/drain regions 52 may be formed on physically exposed surfaces of the semiconductor nanowires 10. The volumes of the gaps 19 are filled with a combination of the dielectric spacer structures 24 and the source/drain regions 52 (which are heavily doped semiconductor material portions). The semiconductor nanowires 10 comprise portions of a single crystalline semiconductor material, and each source/drain region 52 may comprise multiple single crystalline grains having a same set of crystallographic orientations and containing grain boundaries thereamongst. In other words, while the multiple grains of a source/drain region 52 may have the same set of crystallographic orientations such that the spatial crystallographic directions are identical, there may be grain boundaries at the boundaries of the multiple grains. For each vertical stack of dielectric spacer structures 24 interlaced with semiconductor nanowires 10, a pair of source/drain regions 52 laterally spaced from each other by the dielectric spacer structures 24 is formed. In one embodiment, the pair of source/drain regions 52 may be a pair of epitaxial source/drain regions that are epitaxially aligned to the single crystalline semiconductor materials of the semiconductor nanowires 10.

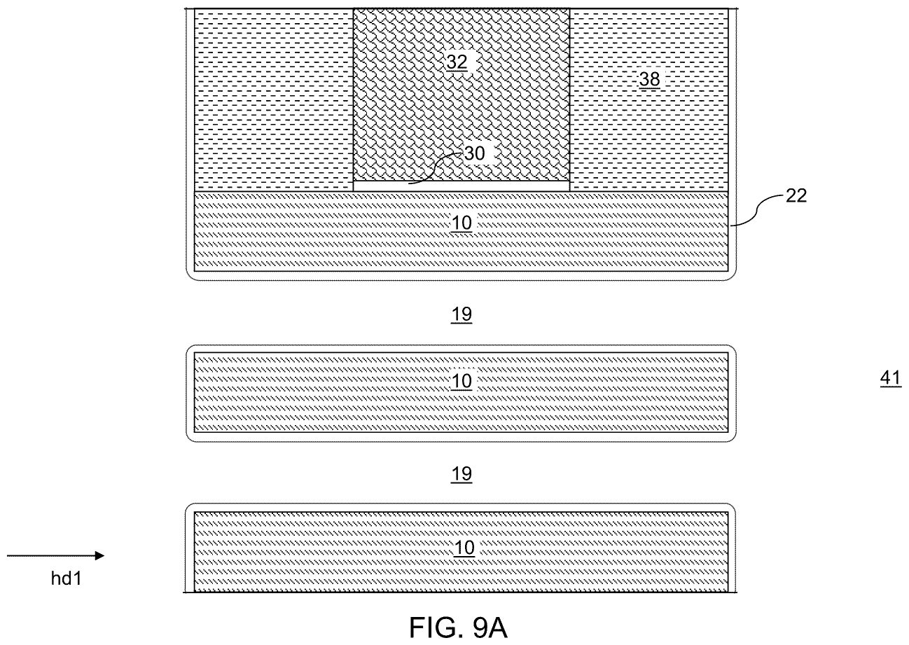

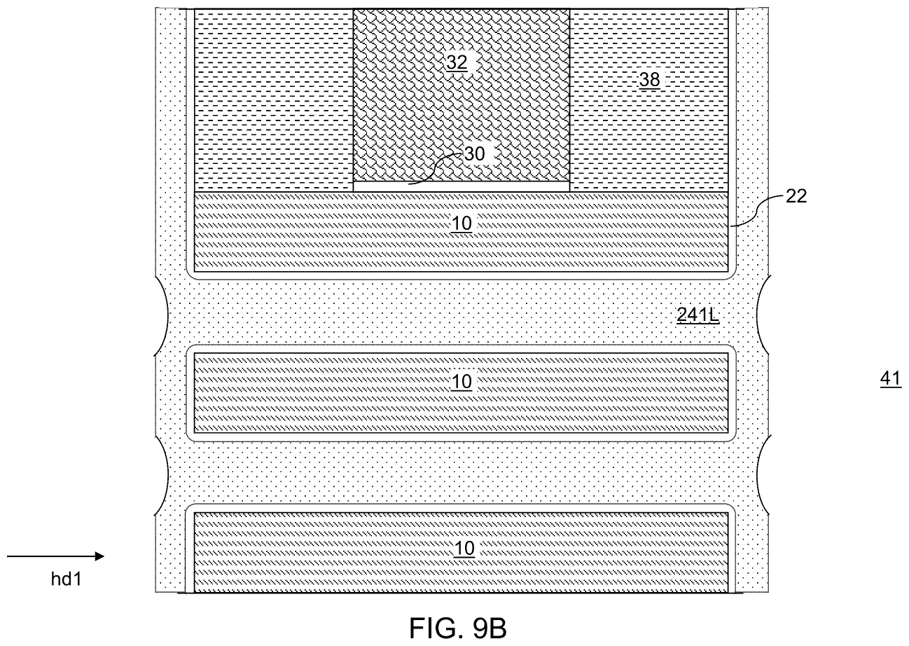

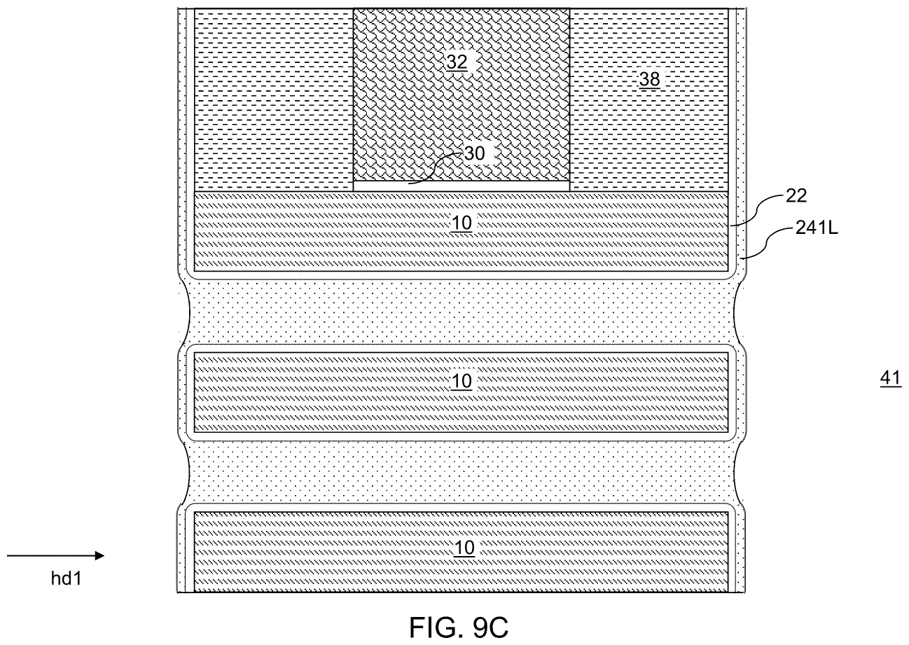

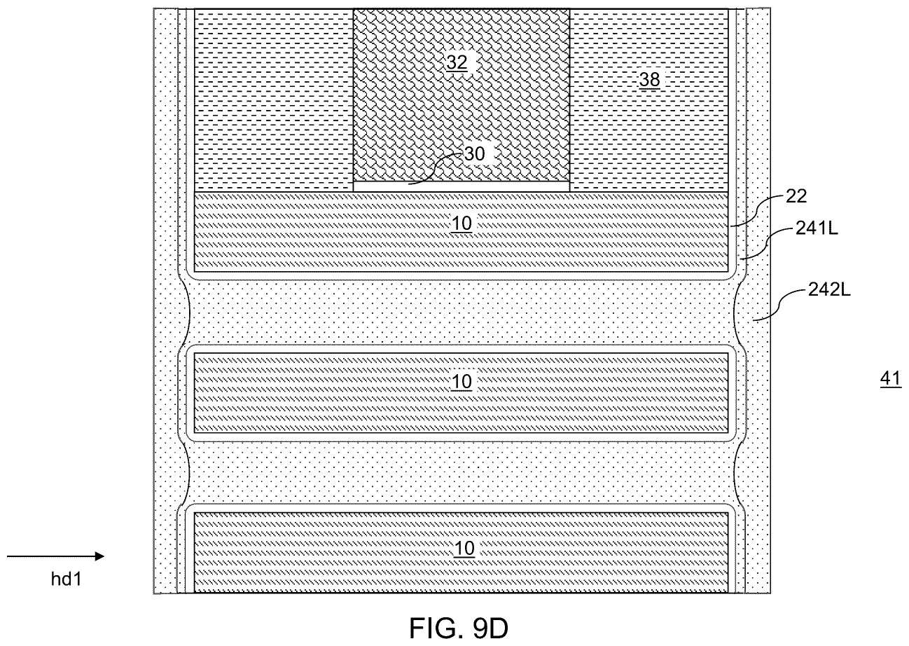

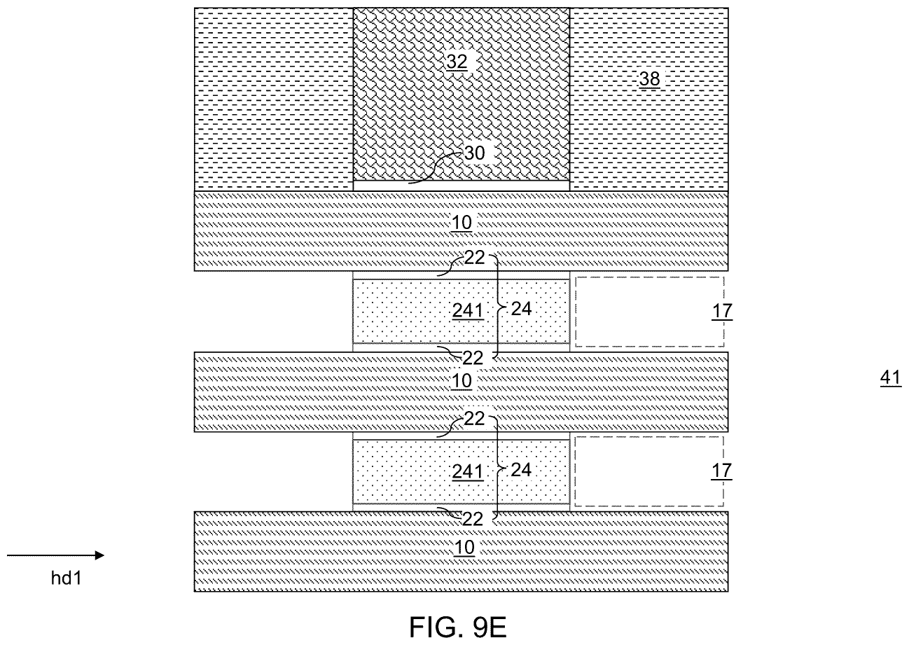

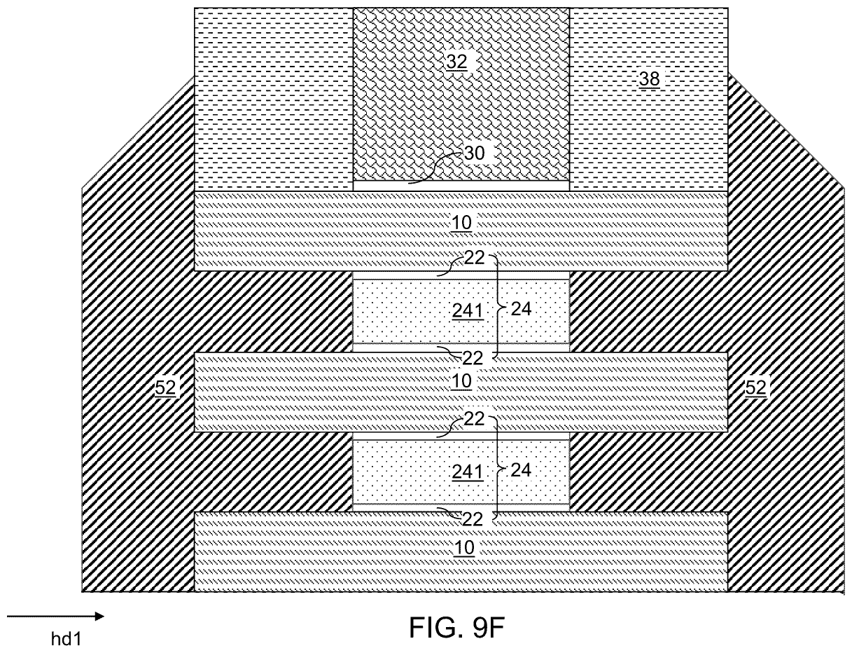

FIGS. 9A-9F are sequential vertical cross-sectional views of a region around semiconductor nanowires 10 during formation of dielectric spacer structures 24 and source/drain regions 52 in a second configuration of the exemplary structure according to an embodiment of the present disclosure.

Referring to FIG. 9A, the second configuration of the exemplary structure may be the same as the first configuration of the exemplary structure illustrated in FIG. 8A.

Referring to FIG. 9B, the first iteration of the sequence that includes a first instance of the flowable chemical vapor deposition process and a first instance of the ultraviolet cure process may be performed as described with reference to FIG. 8B. In the second configuration, the duration of the first instance of the flowable chemical vapor deposition process may be elongated such that the total amount of the deposited dielectric material has the same volume as the sum of the volume of the first dielectric material layer 241L and the volume of the second dielectric material layer 242L as illustrated in FIG. 8C. In other words, the deposition time of the first instance of the flowable chemical vapor deposition process may be extended such that the first dielectric material layer 241L as deposited during the first instance of the flowable chemical vapor deposition process in the second configuration of the exemplary structure may have the same volume as the sum of the volume of the first dielectric material layer 241L and the volume of the second dielectric material layer 242L as illustrated in FIG. 8C. Thus, the first dielectric material layer 241L in the second configuration of the exemplary structure comprises contoured vertically-extending surfaces that comprises planar vertical surface segments at levels of the semiconductor nanowires 10 and concave surface segments at levels of the gaps 19.

Subsequently, the first instance of the ultraviolet cure process may be performed to densify the first dielectric material in the first dielectric material layer 241L. During deposition of the first dielectric material in the first dielectric material layer 241L, surface profiles of the first dielectric material may be the same as described with reference to FIGS. 8B and 8C. Thus, the flowable chemical vapor deposition process may provide inversely non-conformal thickness profile during deposition of the first dielectric material layer 241L, and may provide a seamless complete fill of the entire volumes of the gaps 19 between vertically neighboring pairs of semiconductor nanowires 10 and a single crystalline semiconductor fin 8.

Referring to FIG. 9C, the processing steps described with reference to FIG. 8D may be performed to isotropically recess the first dielectric material layer 241L.

Referring to FIG. 9D, the processing steps described with reference to FIG. 8E may be performed to deposit and cure a second dielectric material layer 242L, which may be compositionally and structurally the same as the third dielectric material layer 243L described with reference to FIG. 8E.

In the second configuration, a first dielectric material that is deposited by the first instance of the flowable chemical vapor deposition process and is cured by the first instance of the ultraviolet cure process fills the gaps 19, and comprises a contoured vertically-extending surface that comprises planar vertical surface segments at levels of the semiconductor nanowires 10 and concave surface segments at levels of the gaps 19. A second dielectric material is deposited by the second instance of the flowable chemical vapor deposition process, and is cured by the second instance of the ultraviolet cure process comprises a planar vertically-extending surface that vertically extends continuously through each level of the semiconductor nanowires 10 and through each level of the gaps 19.

Referring to FIG. 9E, the processing steps described with reference to FIG. 8F may be performed to form dielectric spacer structures 24. Specifically, a selective isotropic etch process may be performed to etch the materials of the conformal dielectric liner 22, the first dielectric material layer 241L, and the second dielectric material layer 242L selective to the materials of the semiconductor nanowires 10, the single crystalline semiconductor fins 8, and the dielectric gate spacers 38. In one embodiment, the selective isotropic etch process may comprise a wet etch process using dilute hydrofluoric acid. The selective isotropic etch process may etch the materials of the conformal dielectric liner 22, the first dielectric material layer 241L, and the second dielectric material layer 242L at the same etch rate. The selective isotropic etch process removes the entirety of the second dielectric material layer 242L. The end sidewalls of the semiconductor nanowires 10 that are perpendicular to the first horizontal direction hd1 may be physically exposed.

Remaining portions of the conformal dielectric liner 22 and the first dielectric material layer 241L comprise dielectric spacer structures 24. Each dielectric spacer structure 24 comprises a pair of conformal dielectric liners 22 and a first dielectric material portion 241. The first dielectric material portion 241 is a remaining portion of the first dielectric material layer 241L. The dielectric spacer structures 24 having a lesser lateral extent than the semiconductor nanowires 10 along the first horizontal direction hd1. In one embodiment, the lateral extent of each dielectric spacer structure 24 may be about the same as the lateral extent of a respective overlying sacrificial gate structure (30, 32, 34, 36). According to an aspect of the present disclosure, each dielectric spacer structure 24 may have a pair of vertical planar sidewalls that are perpendicular to the first horizontal direction hd1. Inter-nanowire cavities 17 may be formed in the voids that are formed within the volumes of the gaps 19 as provided at the processing steps of FIGS. 7A-7E. According to an aspect of the present disclosure, each inter-nanowire cavity 17 may have a volume of a respective rectangular parallelopiped.

Referring to FIG. 9F, a selective semiconductor deposition process described with reference to FIG. 8G may be performed to form source/drain regions 52 on physically exposed surfaces of the semiconductor nanowires 10. The volumes of the gaps 19 are filled with a combination of the dielectric spacer structures 24 and the source/drain regions 52 (which are heavily doped semiconductor material portions). The semiconductor nanowires 10 comprise portions of a single crystalline semiconductor material, and each source/drain region 52 may comprise multiple single crystalline grains having a same set of crystallographic orientations and containing grain boundaries thereamongst. In other words, while the multiple grains of a source/drain region 52 may have the same set of crystallographic orientations such that the spatial crystallographic directions are identical, there may be grain boundaries at the boundaries of the multiple grains. For each vertical stack of dielectric spacer structures 24 interlaced with semiconductor nanowires 10, a pair of source/drain regions 52 laterally spaced from each other by the dielectric spacer structures 24 is formed. In one embodiment, the pair of source/drain regions 52 may be a pair of epitaxial source/drain regions that are epitaxially aligned to the single crystalline semiconductor materials of the semiconductor nanowires 10.

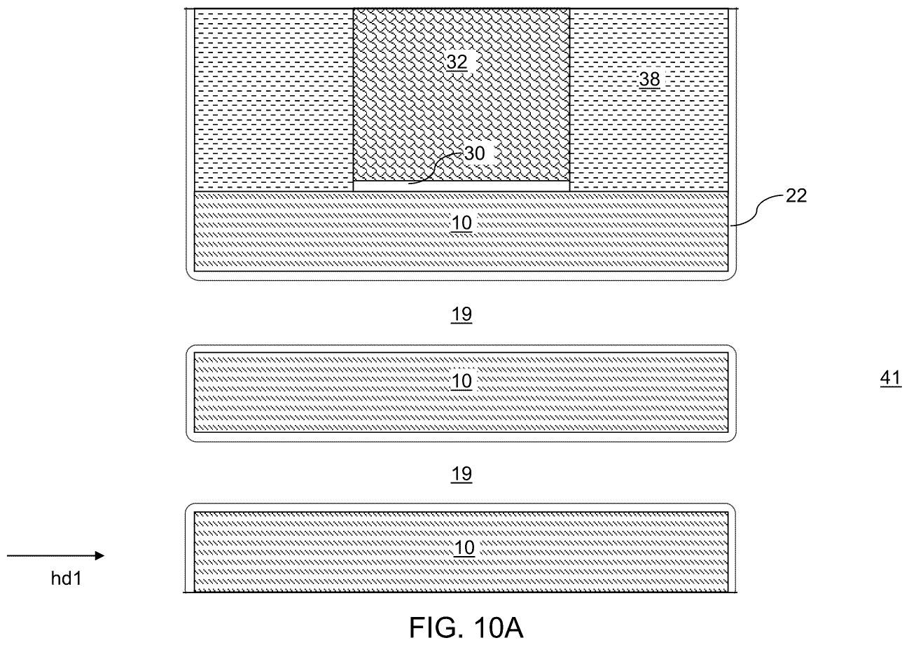

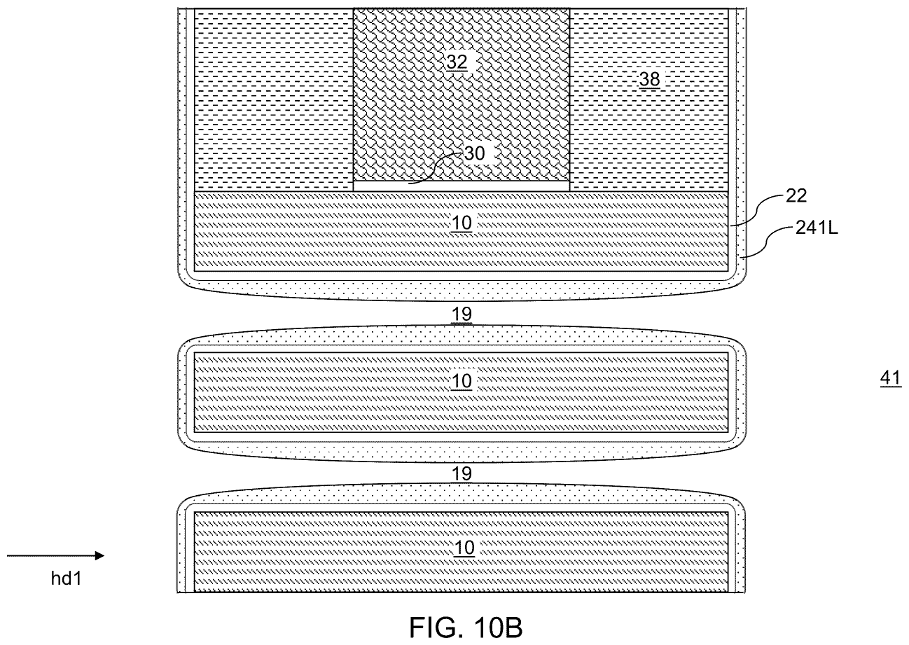

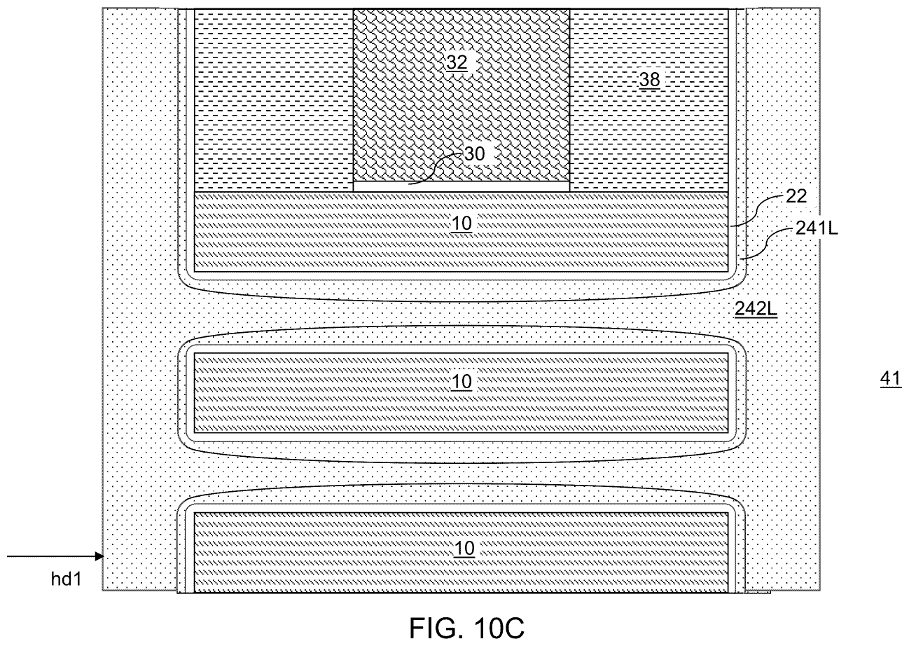

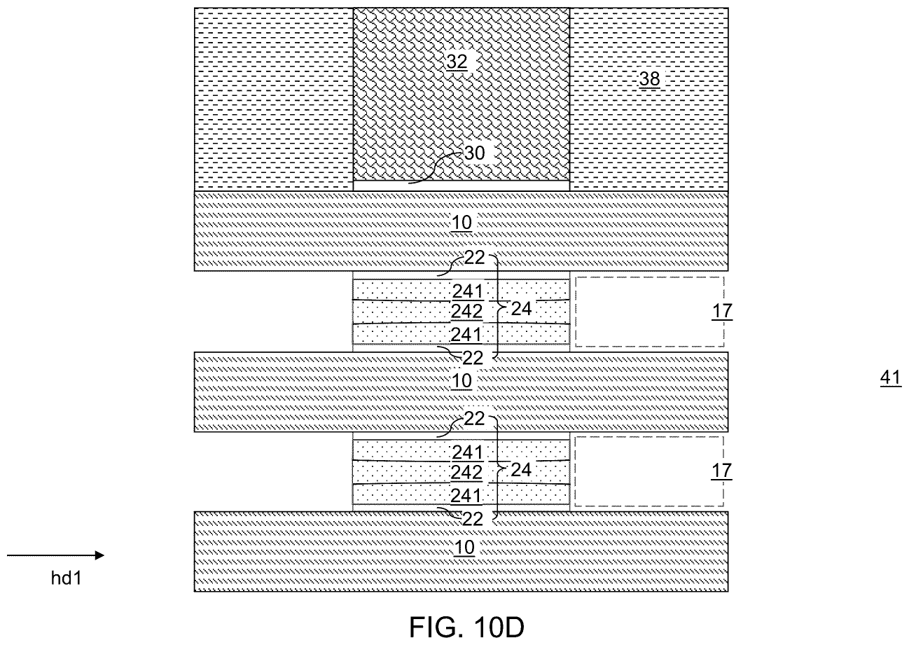

FIGS. 10A-10E are sequential vertical cross-sectional views of a region around semiconductor nanowires 10 during formation of dielectric spacer structures 24 and source/drain regions 52 in a third configuration of the exemplary structure according to an embodiment of the present disclosure.

Referring to FIG. 10A, the third configuration of the exemplary structure may be the same as the first configuration of the exemplary structure illustrated in FIG. 8A.

Referring to FIG. 10B, the processing steps described with reference to FIG. 8B may be performed. Specifically, the first iteration of the sequence that includes a first instance of the flowable chemical vapor deposition process and a first instance of the ultraviolet cure process may be performed as described with reference to FIG. 8B.

Referring to FIG. 10C, the processing steps described with reference to FIG. 8C may be performed. Specifically, the second iteration of the sequence that includes a second instance of the flowable chemical vapor deposition process and a second instance of the ultraviolet cure process may be performed with a modification in the duration of the second instance of the flowable chemical vapor deposition process such that the total amount of the deposited dielectric material has the same volume as the sum of the volume of the second dielectric material portions 242 and the volume of the third dielectric material layer 243L as illustrated in FIG. 8E. Thus, the second dielectric material layer 242L in the third configuration of the exemplary structure comprises planar vertical surfaces that are perpendicular to the first horizontal direction hd1 and vertically extending from the horizontal plane including the bottommost surfaces of the semiconductor nanowires 10 to the horizontal plane including the topmost surfaces of the semiconductor nanowires 10.

Subsequently, the second instance of the ultraviolet cure process may be performed to densify the second dielectric material in the second dielectric material layer 242L. As discussed above with reference to the first and second configurations of the exemplary structure, the flowable chemical vapor deposition processes may provide inversely non-conformal thickness profile during deposition of the first dielectric material layer 241L and the second dielectric material layer 242L, and may provide a seamless complete fill of the entire volumes of the gaps 19 between vertically neighboring pairs of semiconductor nanowires 10 and a single crystalline semiconductor fin 8.

Referring to FIG. 10D, the processing steps described with reference to FIG. 8E may be performed to isotropically recess the first dielectric material layer 241L and the second dielectric material layer 242L. Specifically, a selective isotropic etch process may be performed to etch the materials of the conformal dielectric liner 22, the first dielectric material layer 241L, and the second dielectric material layer 242L selective to the materials of the semiconductor nanowires 10, the single crystalline semiconductor fins 8, and the dielectric gate spacers 38. In one embodiment, the selective isotropic etch process may comprise a wet etch process using dilute hydrofluoric acid. The selective isotropic etch process may etch the materials of the conformal dielectric liner 22, the first dielectric material layer 241L, and the second dielectric material layer 242L at the same etch rate. The end sidewalls of the semiconductor nanowires 10 that are perpendicular to the first horizontal direction hd1 may be physically exposed.

Remaining portions of the conformal dielectric liner 22, the first dielectric material layer 241L, and the second dielectric material layer 242L comprise dielectric spacer structures 24. Each dielectric spacer structure 24 comprises a pair of conformal dielectric liners 22, a first dielectric material portion 241 having a tubular configuration, and a second dielectric material portion 242. The first dielectric material portion 241 is a remaining portion of the first dielectric material layer 241L. The second dielectric material portion 242 is a remaining portion of the second dielectric material layer 242L. The dielectric spacer structures 24 having a lesser lateral extent than the semiconductor nanowires 10 along the first horizontal direction hd1. In one embodiment, the lateral extent of each dielectric spacer structure 24 may be about the same as the lateral extent of a respective overlying sacrificial gate structure (30, 32, 34, 36). According to an aspect of the present disclosure, each dielectric spacer structure 24 may have a pair of vertical planar sidewalls that are perpendicular to the first horizontal direction hd1. Inter-nanowire cavities 17 may be formed in the voids that are formed within the volumes of the gaps 19 as provided at the processing steps of FIGS. 7A-7E. According to an aspect of the present disclosure, each inter-nanowire cavity 17 may have a volume of a respective rectangular parallelopiped.

Referring to FIG. 10E, a selective semiconductor deposition process described with reference to FIG. 8G may be performed to form source/drain regions 52 on physically exposed surfaces of the semiconductor nanowires 10. The volumes of the gaps 19 are filled with a combination of the dielectric spacer structures 24 and the source/drain regions 52 (which are heavily doped semiconductor material portions). The semiconductor nanowires 10 comprise portions of a single crystalline semiconductor material, and each source/drain region 52 may comprise multiple single crystalline grains having a same set of crystallographic orientations and containing grain boundaries thereamongst. In other words, while the multiple grains of a source/drain region 52 may have the same set of crystallographic orientations such that the spatial crystallographic directions are identical, there may be grain boundaries at the boundaries of the multiple grains. For each vertical stack of dielectric spacer structures 24 interlaced with semiconductor nanowires 10, a pair of source/drain regions 52 laterally spaced from each other by the dielectric spacer structures 24 is formed. In one embodiment, the pair of source/drain regions 52 may be a pair of epitaxial source/drain regions that are epitaxially aligned to the single crystalline semiconductor materials of the semiconductor nanowires 10.

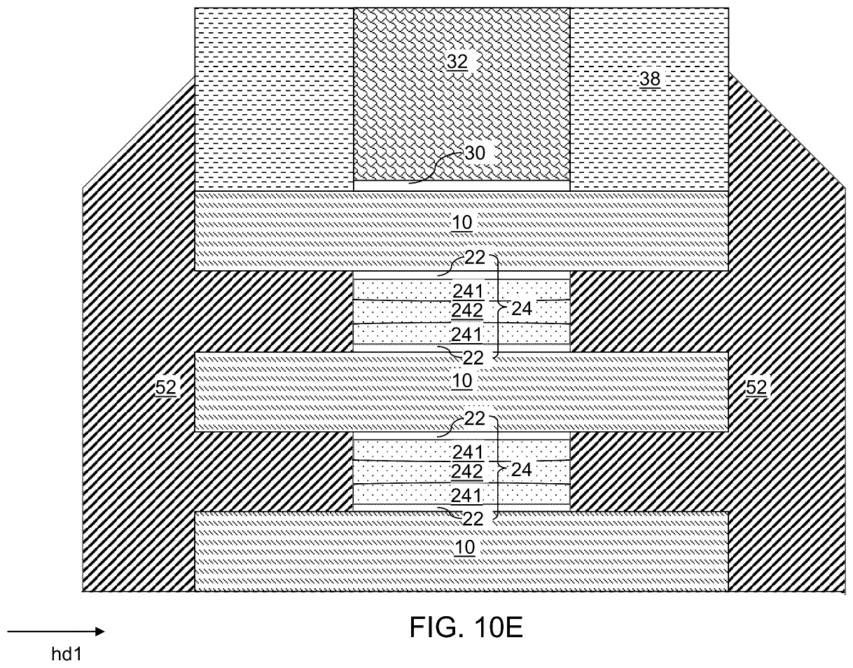

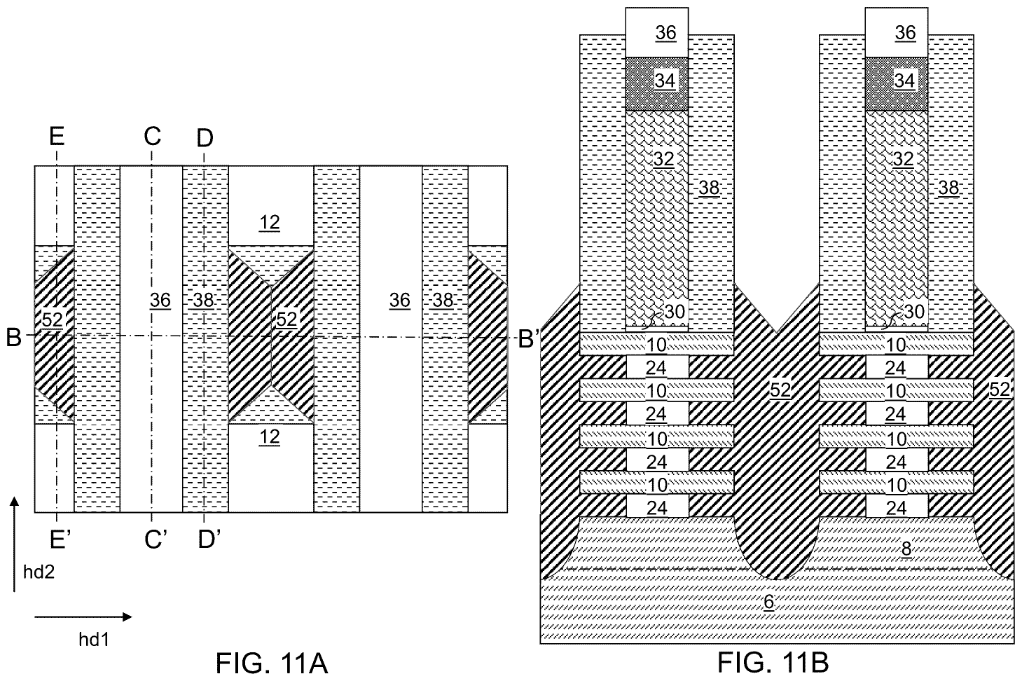

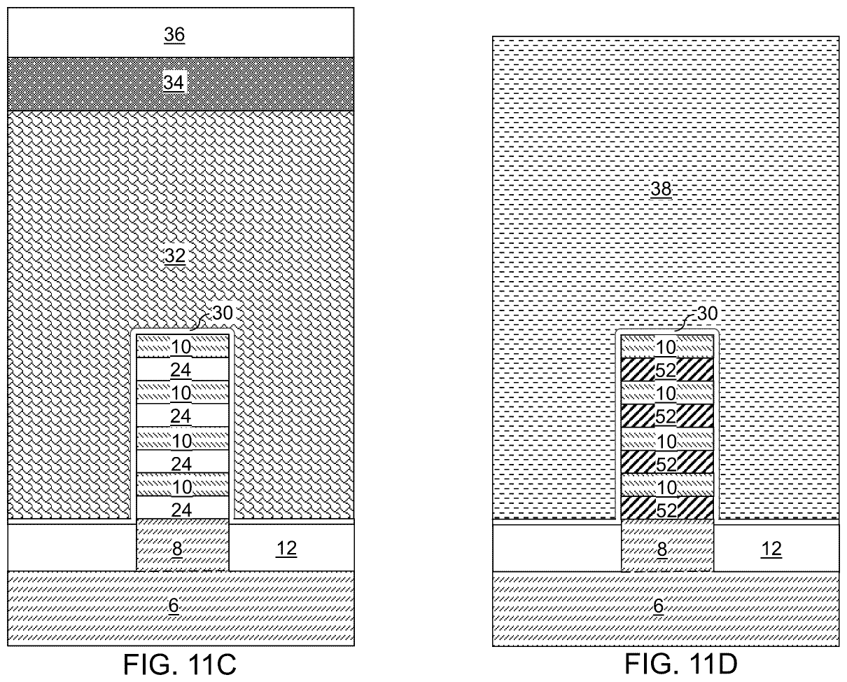

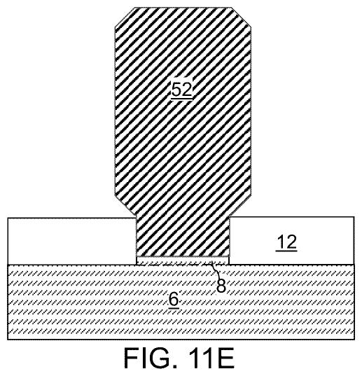

Referring to FIGS. 11A-11E, the exemplary structure is illustrated after formation of source/drain regions 52, i.e., after the processing steps described with reference to FIGS. 8G, 9F, or 10E. Generally, a selective semiconductor deposition process may be performed to grow a semiconductor material portion comprising a heavily doped semiconductor material from physically exposed surfaces of the semiconductor nanowires 10 while suppressing growth of the semiconductor material from surfaces of the of the dielectric spacer structures 24. The volumes of the gaps 19 are filled with a combination of the dielectric spacer structures 24 and the semiconductor material portion. Source/drain regions 52 on physically exposed surfaces of the semiconductor nanowires 10, and the semiconductor nanowires 10 may comprise portions of a single crystalline semiconductor material. In one embodiment, the selective semiconductor deposition process may comprise a selective epitaxy process that grows a doped epitaxial semiconductor material from physically exposed surfaces of the semiconductor nanowires 10. A pair of source/drain regions 52 laterally spaced from each other by the dielectric spacer structures 24 may be formed. In one embodiment, the pair of source/drain regions 52 may be a pair of epitaxial source/drain regions that are epitaxially aligned to the single crystalline semiconductor materials of the semiconductor nanowires 10.

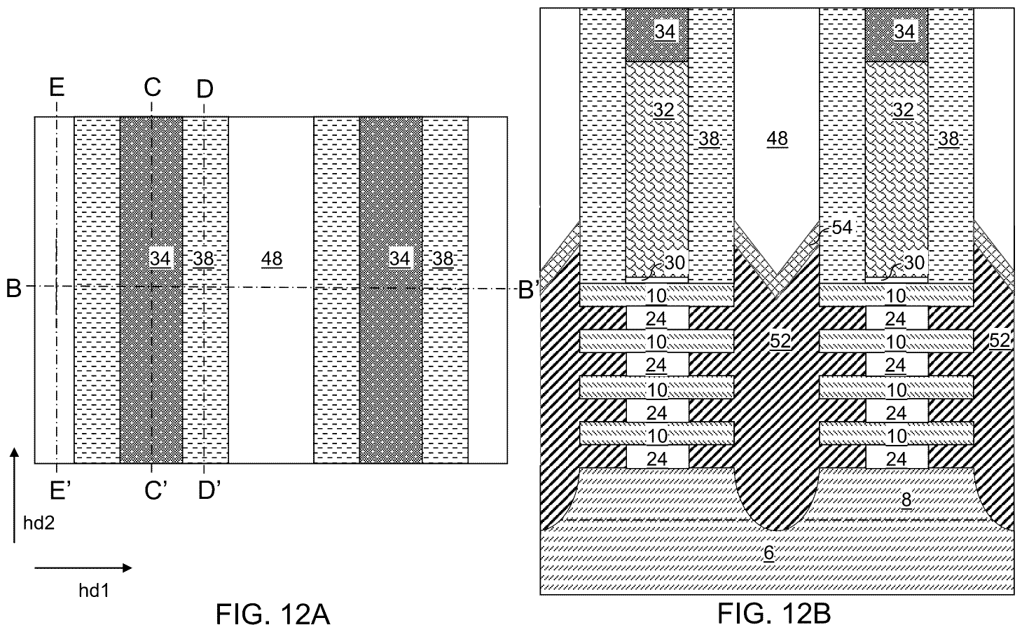

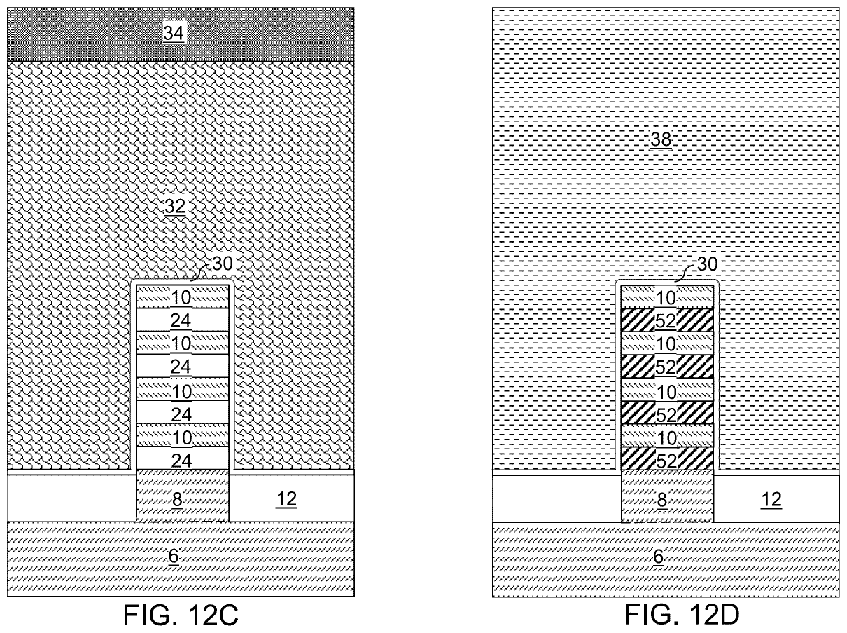

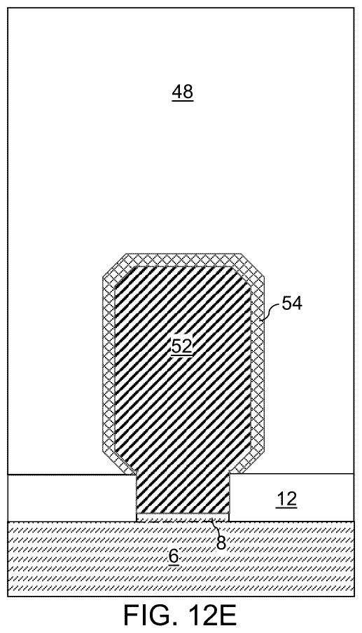

Referring to FIGS. 12A-12E, metal-semiconductor alloy portions 54 including an alloy of the semiconductor material of the source/drain regions 52 and a metal may be formed on the physically exposed surfaces of the source/drain regions 52. For example, a metal that forms a metal silicide upon reaction with silicon may be deposited on the source/drain regions 52, and may be annealed at an elevated temperature to form the metal-semiconductor alloy portions 54. Unreacted portions of the metal may be removed selective to the metal-semiconductor alloy portions 54 by performing a selective etch process.

A planarizable dielectric material such as silicon oxide may be deposited over the metal-semiconductor alloy portions 54 and the sacrificial gate structures (30, 32, 34, 36). A planarization process such as a chemical mechanical polishing process may be performed to remove portions of the deposited planarizable dielectric material, the second gate hardmask portions 36, and the dielectric gate spacers 38 from above the horizontal plane including the top surfaces of the first gate hardmask portions 34. In one embodiment, the first gate hardmask portions 34 may comprise silicon nitride, and may be used as stopping structures during the planarization process. The remaining portions of the planarizable dielectric material comprise a contact-level dielectric layer 48. The top surface of the contact-level dielectric layer 48 may be coplanar with the top surfaces of the first gate hardmask portions 34.

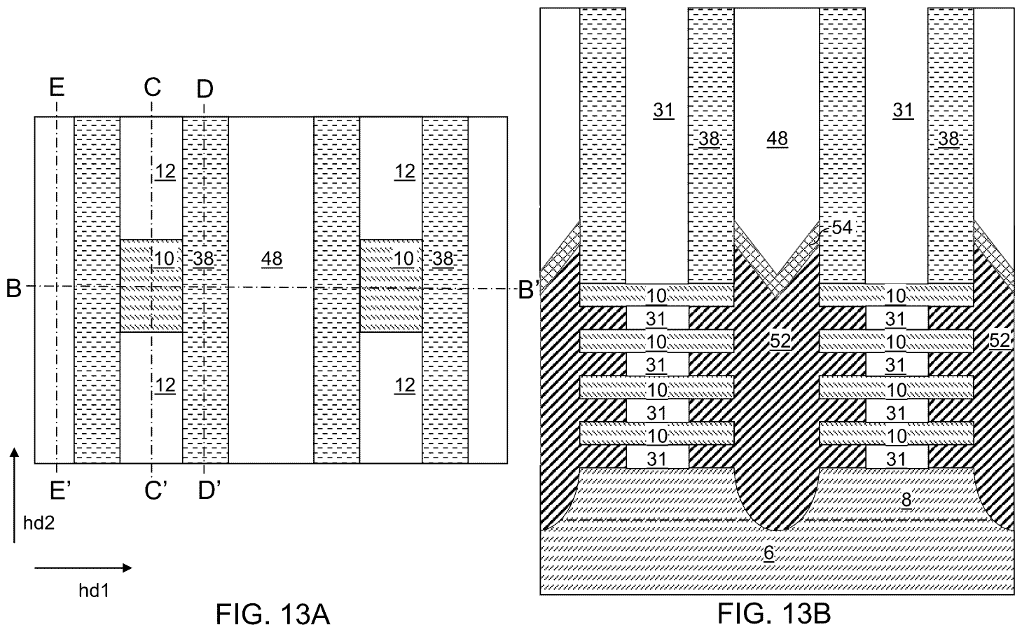

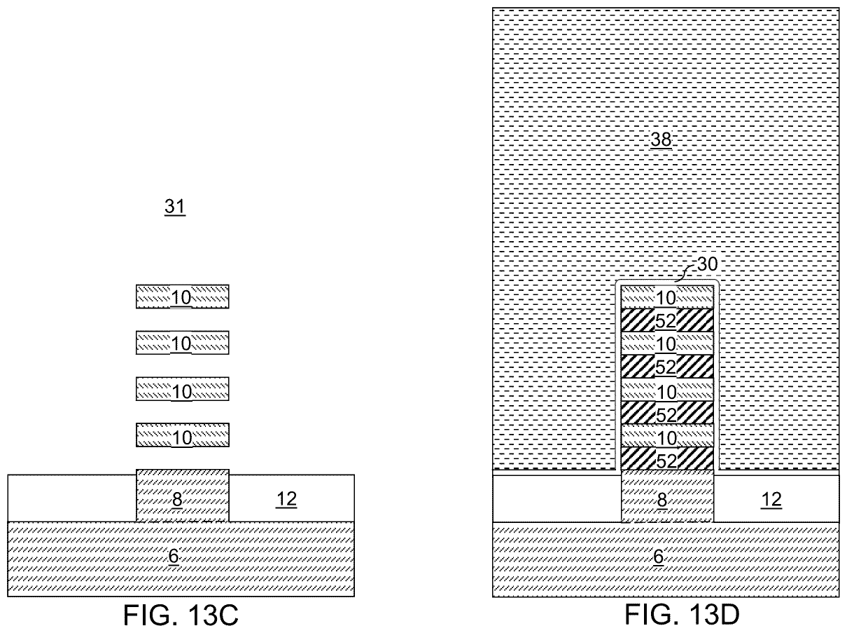

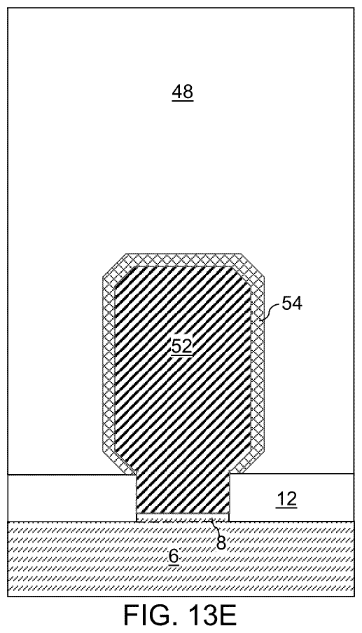

Referring to FIGS. 13A-13E, a first selective etch process may be performed to etch the material of the first gate hardmask portions 34 selective to the materials of the contact-level dielectric layer 48, the dielectric gate spacers 38, and the sacrificial gate electrodes 32. For example, if the first gate hardmask portions 34 comprise silicon nitride, a wet etch process using hot phosphoric acid may be performed to remove the first gate hardmask portions 34.

A second selective etch process may be performed to etch the material of the sacrificial gate electrodes 32 selective to the materials of the contact-level dielectric layer 48, the dielectric gate spacers 38, and the sacrificial dielectric liners 30. For example, if the sacrificial gate electrodes 32 comprise a silicon-germanium alloy, a wet etch process using a mixture of nitric acid, acetic acid, hydrofluoric acid, and deionized water may be used to etch to remove the sacrificial gate electrodes 32.

A third selective etch process may be performed to isotropically etch the sacrificial dielectric liners 30 and the dielectric spacer structures 24 selective to the semiconductor nanowires 10 and the dielectric gate spacers 38. For example, a wet etch process using dilute hydrofluoric acid may be performed to remove the sacrificial dielectric liners 30 and the dielectric spacer structures 24. Gate cavities 31 are formed in the volumes from which the first gate hardmask portions 34, the sacrificial gate electrodes 32, the sacrificial dielectric liners 30, and the dielectric spacer structures 24 are removed. Planar vertical sidewalls of the source/drain regions 52 that are perpendicular to the first horizontal direction hd1 may be exposed to the gate cavities 31.

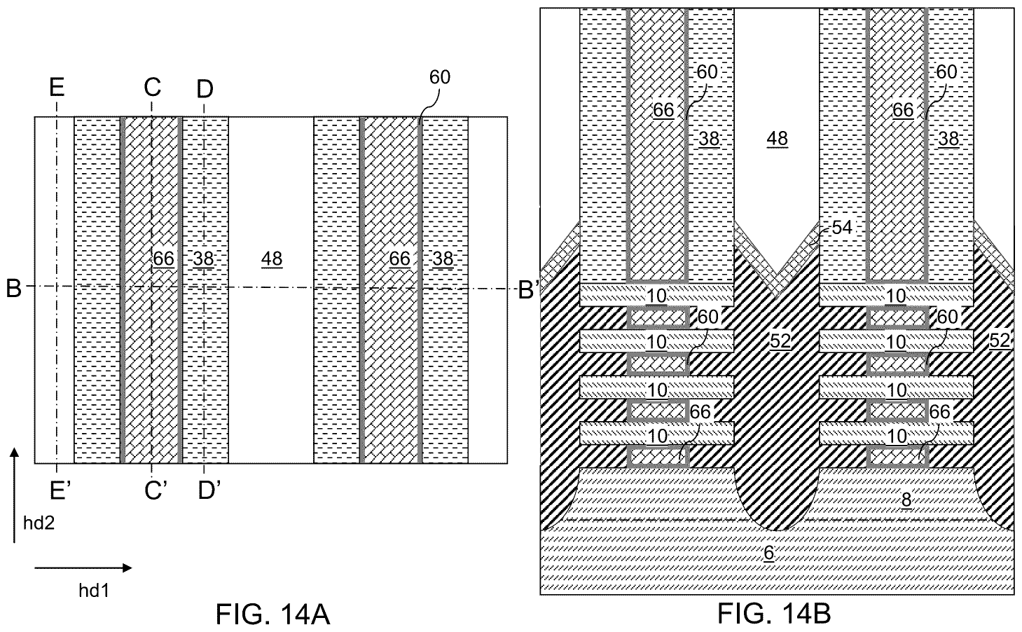

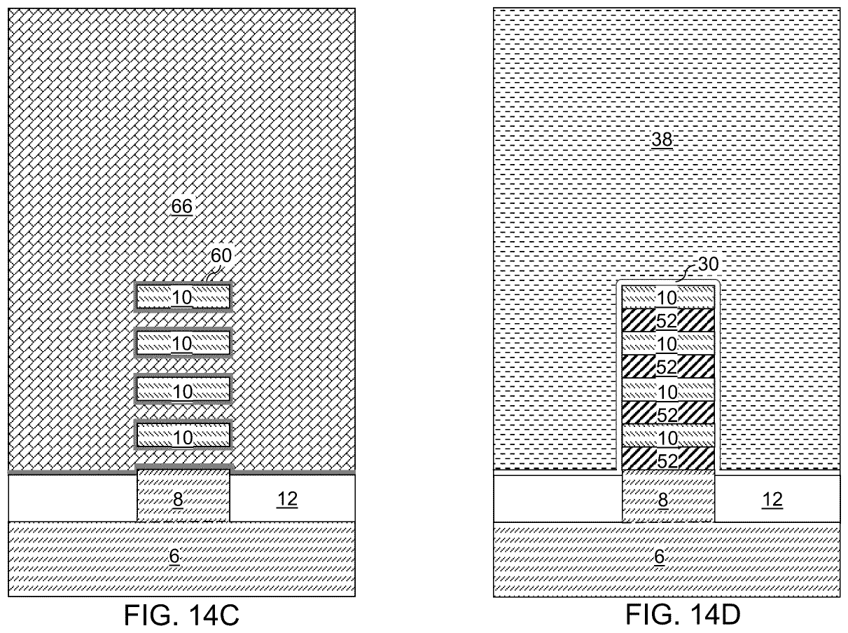

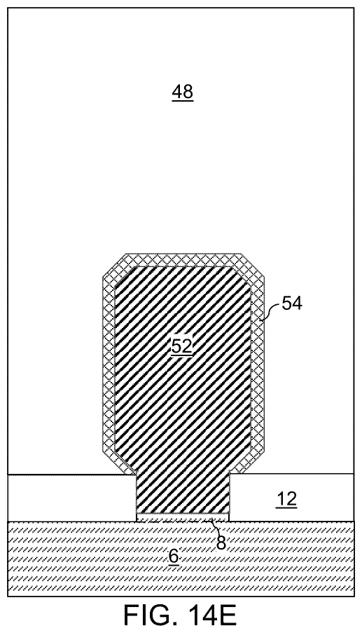

Referring to FIGS. 14A-14E, a gate dielectric 60 and a gate electrode 66 may be formed within each gate cavity 31. For example, a continuous gate dielectric material layer may be conformally deposited, for example, by atomic layer deposition. The continuous gate dielectric material layer may include a dielectric metal oxide material having a dielectric constant greater than 7.9. Dielectric metal oxide materials having a dielectric constant greater than 7.9 are referred to high dielectric constant (high-k) metal oxide materials. Exemplary high-k dielectric metal oxide materials include, but are not limited to, aluminum oxide, hafnium oxide, yttrium oxide, lanthanum oxide, zirconium oxide, tantalum oxide, and strontium oxide. Optionally, the continuous gate dielectric material layer may additionally include a silicon oxide layer. The thickness of the continuous gate dielectric material layer may be in a range from 1 nm to 6 nm, such as from 1.5 nm to 3 nm, although lesser and greater thicknesses may also be used.

A continuous gate electrode metal layer may be deposited over the continuous gate dielectric material layer. The continuous gate electrode metal layer includes an optional metallic liner layer including a conductive metallic nitride material such as TiN, TaN, or WN, and a metallic fill material such as tungsten, ruthenium, molybdenum, cobalt, tantalum, or titanium. Excess portions of the continuous gate electrode metal layer and the continuous gate dielectric material layer may be removed from above the horizontal plane including the top surface of the contact-level dielectric layer 48. Each remaining portion of the continuous gate dielectric material layer comprises a gate dielectric 60. Each remaining portion of the continuous gate electrode material layer comprises a gate electrode 66. Each gate dielectric 60 and each gate electrode 66 may laterally extend along the second horizontal direction hd2.

Generally, each contiguous combination of a first gate hardmask portion 34, a sacrificial gate electrode 32, a sacrificial dielectric liners 30, and dielectric spacer structures 24 may be replaced with a combination of a gate dielectric 60 and a gate electrode 66.

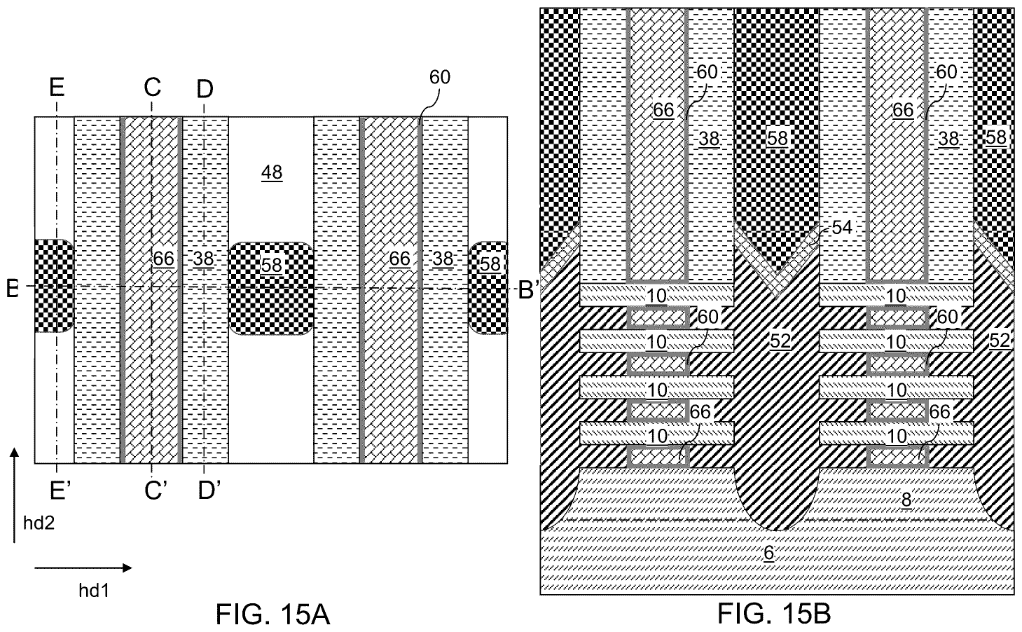

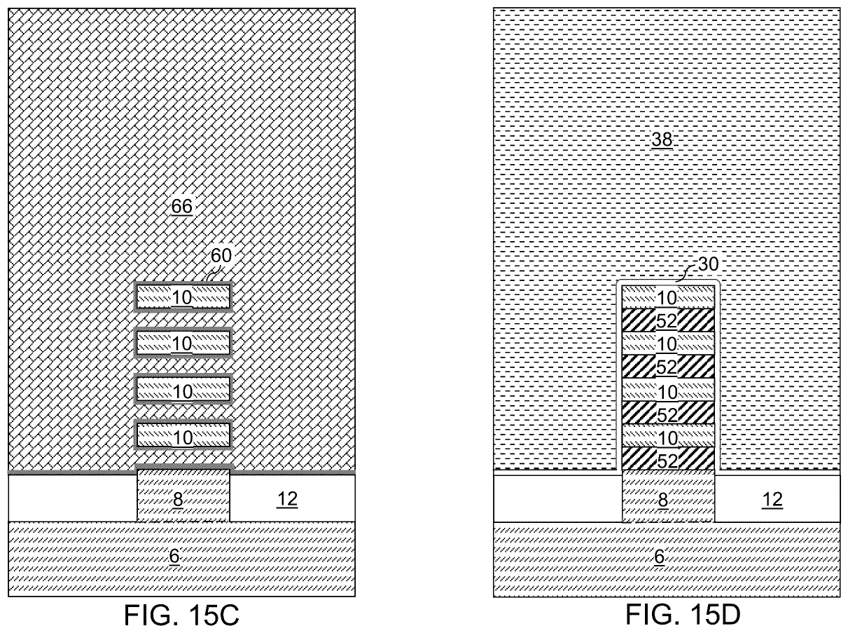

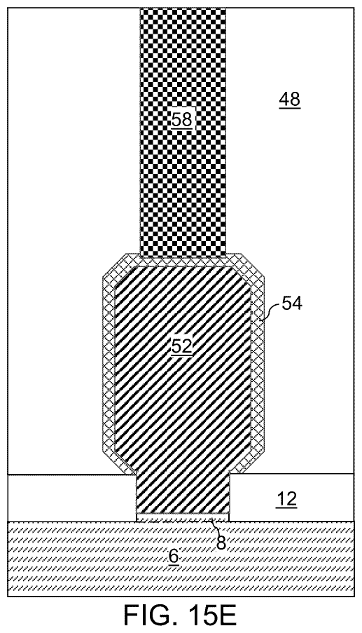

Referring to FIGS. 15A-15E, source/drain contact via structures 58 may be formed through the contact-level dielectric layer 48 on a respective one of the metal-semiconductor alloy portions 54.

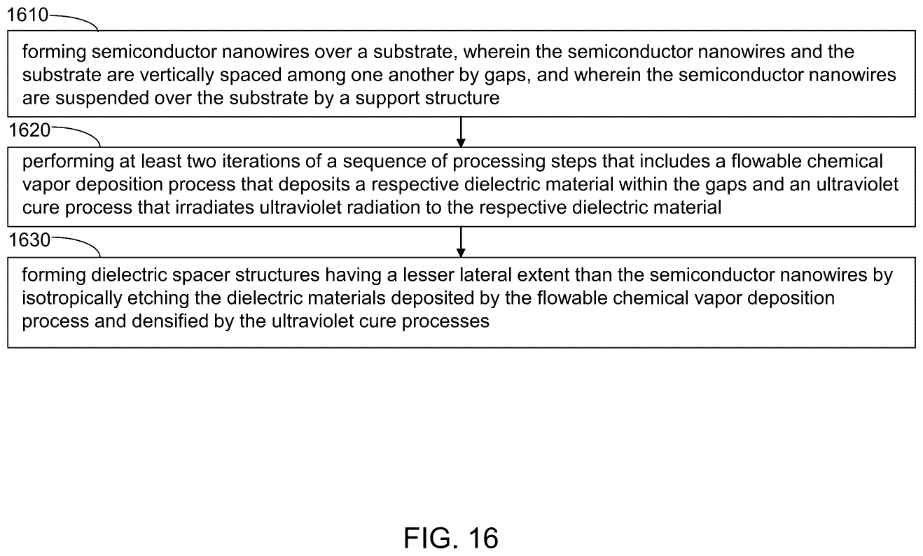

Referring to FIG. 16, a first flowchart illustrates steps for forming a semiconductor structure of the present disclosure.

Referring step 1610 and FIGS. 1A-7E, semiconductor nanowires 10 are formed over a substrate 6. The semiconductor nanowires 10 and the substrate 6 are vertically spaced from one another by gaps 19. The semiconductor nanowires 10 are suspended over the substrate 6 by a support structure such as a sacrificial gate structure (30, 32, 34, 36).

Referring to step 1620 and FIGS. 8A-8E, 9A-9D, and 10A-10C, at least two iterations of a sequence of processing steps may be performed. The sequence of processing steps includes a flowable chemical vapor deposition process that deposits a respective dielectric material and an ultraviolet cure process that irradiates ultraviolet radiation to the respective dielectric material.

Referring to step 1630 and FIGS. 8F, 8G, 9E, 9F, 10D, and 10E, dielectric spacer structures 24 having a lesser lateral extent than the semiconductor nanowires 10 may be formed by isotropically etching the dielectric materials deposited by the flowable chemical vapor deposition process and densified by the ultraviolet cure processes.

In one embodiment, the dielectric materials deposited by the instances of the flowable chemical vapor deposition process fill a volume of each of the gaps 19. In one embodiment, the at least two iterations of the sequence include: a first iteration of the sequence that includes a first instance of the flowable chemical vapor deposition process and a first instance of the ultraviolet cure process; and a second iteration of the sequence that includes a second instance of the flowable chemical vapor deposition process and a second instance of the ultraviolet cure process. In one embodiment, the first instance of the flowable chemical vapor deposition process deposits a first dielectric material 241 on horizontal surfaces of the semiconductor nanowires 10 such that the first dielectric material 241 has a greater thickness at a center portion of each of the horizontal surfaces of the semiconductor nanowires 10 than peripheral portions of each of the horizontal surfaces of the semiconductor nanowires. In one embodiment, a second dielectric material 242 that is deposited by the second instance of the flowable chemical vapor deposition process and is cured by the second instance of the ultraviolet cure process fills the gaps 19, and comprises a contoured vertically-extending surface that comprises concave surface segments at levels of the gaps 19. In one embodiment, the at least two iterations of the sequence comprises a third iteration of the sequence that includes a third instance of the flowable chemical vapor deposition process and a third instance of the ultraviolet cure process; and a third dielectric material 243 that is deposited by the third instance of the flowable chemical vapor deposition process and is cured by the third instance of the ultraviolet cure process comprises a planar vertically-extending surface that vertically extends continuously through each level of the semiconductor nanowires 10 and through each level of the gaps 19. In one embodiment, each horizontally-extending portion of a first dielectric material 241 that is deposited by the first instance of the flowable chemical vapor deposition process has a physically exposed surface after the first instance of the flowable chemical vapor deposition process; and the physically exposed surfaces has a convex vertical cross-sectional profile in a vertical cross-sectional view along a vertical plane that is parallel to a lengthwise direction of the semiconductor nanowires 10. In one embodiment, a first dielectric material 241 that is deposited by the first instance of the flowable chemical vapor deposition process has a greater thickness on a center portion of a horizontally-extending surface of one of the semiconductor nanowires 10 than on a sidewall of said one of the semiconductor nanowires 10. In one embodiment, a first dielectric material 241 that is deposited by the first instance of the flowable chemical vapor deposition process and is cured by the first instance of the ultraviolet cure process fills the gaps 19, and comprises a contoured vertically-extending surface that comprises concave surface segments at levels of the gaps 19. In one embodiment, a second dielectric material 242 that is deposited by the second instance of the flowable chemical vapor deposition process and is cured by the second instance of the ultraviolet cure process comprises a planar vertically-extending surface that vertically extends continuously through each level of the semiconductor nanowires 10 and through each level of the gaps 19.

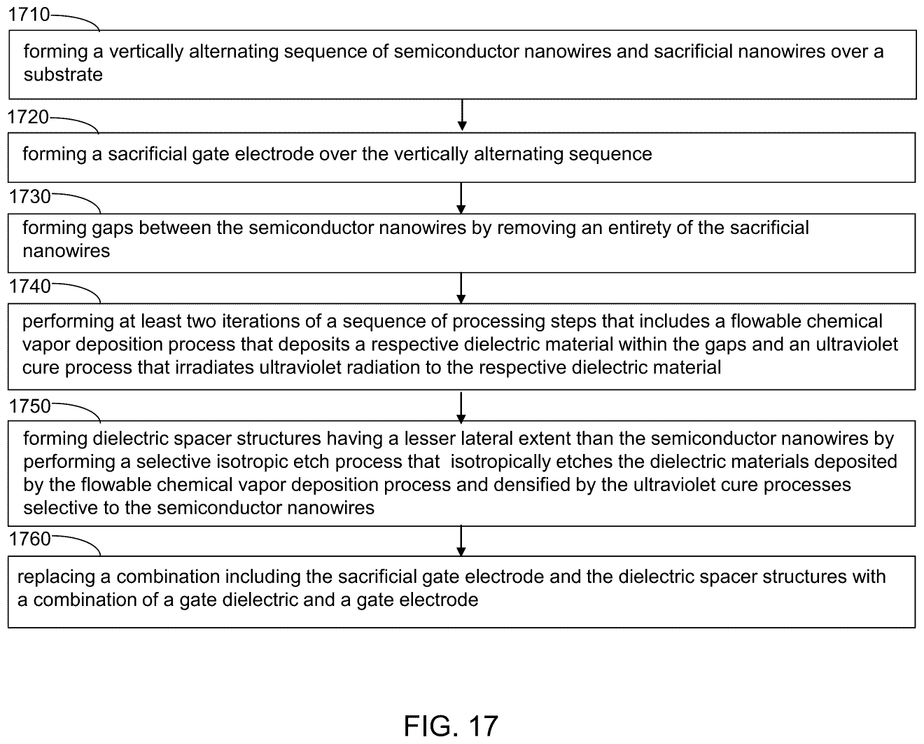

Referring to FIG. 17, a second flowchart illustrates steps for forming a field effect transistor.

Referring to step 1710 and FIGS. 1A-2C, a vertically alternating sequence (10, 20) of semiconductor nanowires 10 and sacrificial nanowires 20 may be formed over a substrate 6.

Referring to step 1720 and FIGS. 3A-4D, a sacrificial gate electrode 32 may be formed over the vertically alternating sequence (10, 20).

Referring to step 1730 and FIGS. 5A-7E, gaps 19 may be formed between the semiconductor nanowires 10 by removing an entirety of the sacrificial nanowires 20.

Referring to step 1740 and FIGS. 8A-8E, 9A-9D, and 10A-10C, at least two iterations of a sequence of processing steps may be performed. The sequence of processing steps includes a flowable chemical vapor deposition process that deposits a respective dielectric material and an ultraviolet cure process that irradiates ultraviolet radiation to the respective dielectric material.

Referring to step 1750 and FIGS. 8F, 9E, and 10D, dielectric spacer structures 24 having a lesser lateral extent than the semiconductor nanowires 10 may be formed by performing a selective isotropic etch process. The selective isotropic etch process isotropically etches the dielectric materials deposited by the flowable chemical vapor deposition process and densified by the ultraviolet cure processes selective to the semiconductor nanowires 10.

Referring to step 1760 and FIGS. 8G, 9F, and 10E, a combination including the sacrificial gate electrode 32 and the dielectric spacer structures 24 may be replaced with a combination of a gate dielectric 60 and a gate electrode 66.

In one embodiment, the at least two iterations of the sequence comprises a first iteration of the sequence that includes a first instance of the flowable chemical vapor deposition process and a first instance of the ultraviolet cure process; and the first instance of the flowable chemical vapor deposition process deposits a first dielectric material 241 on horizontal surfaces of the semiconductor nanowires 10 with a non-uniform thickness distribution such that the first dielectric material has a greater thickness at a center portion of each of the horizontal surfaces of the semiconductor nanowires 10 than peripheral portions of each of the horizontal surfaces of the semiconductor nanowires 10. In one embodiment, the at least two iterations of the sequence comprises a second iteration of the sequence that includes a second instance of the flowable chemical vapor deposition process and a second instance of the ultraviolet cure process; and a second dielectric material that is deposited by the second instance of the flowable chemical vapor deposition process and is cured by the second instance of the ultraviolet cure process fills the gaps 19, and comprises a contoured vertically-extending surface that comprises concave surface segments at levels of the gaps 19. In one embodiment, the selective isotropic etch process etches each of the dielectric materials at a same etch rate; and sidewalls of the dielectric spacers are formed within a pair of parallel planar vertical planes upon termination of the selective isotropic etch process. In one embodiment, the method may further include performing a selective semiconductor deposition process that grows a semiconductor material portion comprising a semiconductor material from physically exposed surfaces of the semiconductor nanowires while suppressing growth of the semiconductor material from surfaces of the of the dielectric spacer structures, whereby the volumes of the gaps 19 are filled with a combination of the dielectric spacer structures and the semiconductor material portion.

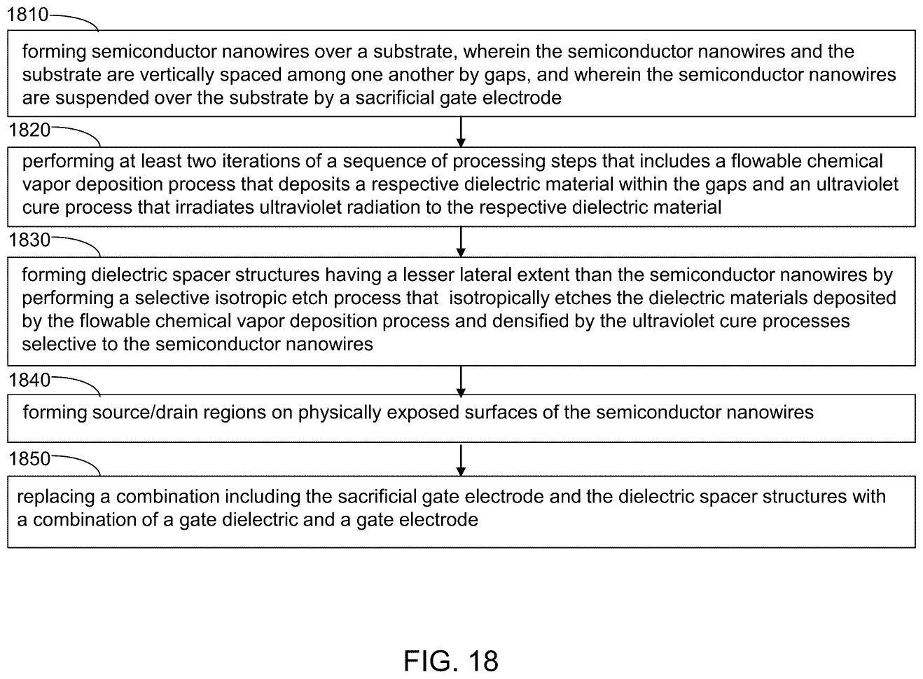

Referring to FIG. 18, a third flowchart illustrates steps for forming a gate-all-around field effect transistor.

Referring to step 1810 and FIGS. 1A-7D, semiconductor nanowires 10 may be formed over a substrate 6. The semiconductor nanowires 10 and the substrate 6 are vertically spaced from one another by gaps 19. The semiconductor nanowires 10 are suspended over the substrate 6 by a sacrificial gate electrode 32.

Referring to step 1820 and FIGS. 8A-8E, 9A-9D, and 10A-10C, at least two iterations of a sequence of processing steps may be performed. The sequence of processing steps includes a flowable chemical vapor deposition process that deposits a respective dielectric material and an ultraviolet cure process that irradiates ultraviolet radiation to the respective dielectric material.

Referring to step 1830 and FIGS. 8F, 9E, and 10D, dielectric spacer structures 24 having a lesser lateral extent than the semiconductor nanowires 10 may be formed by performing a selective isotropic etch process that isotropically etches the dielectric materials deposited by the flowable chemical vapor deposition process and densified by the ultraviolet cure processes selective to the semiconductor nanowires 10.

Referring to step 1840 and FIGS. 8G, 9F, and 10E, source/drain regions 52 may be formed on physically exposed surfaces of the semiconductor nanowires 10.

Referring to step 1850 and FIGS. 11A-15F, a combination including the sacrificial gate electrode 32 and the dielectric spacer structures 24 may be replaced with a combination of a gate dielectric 60 and a gate electrode 66 may be formed.

In one embodiment, the at least two iterations of the sequence comprises a first iteration of the sequence that includes a first instance of the flowable chemical vapor deposition process and a first instance of the ultraviolet cure process; each horizontally-extending portion of a first dielectric material 241 that is deposited by the first instance of the flowable chemical vapor deposition process has a physically exposed surface after the first instance of the flowable chemical vapor deposition process; and the physically exposed surfaces has a convex vertical cross-sectional profile in a vertical cross-sectional view along a vertical plane that is parallel to a lengthwise direction of the semiconductor nanowires 10. In one embodiment, the at least two iterations of the sequence comprises a second iteration of the sequence that includes a second instance of the flowable chemical vapor deposition process and a second instance of the ultraviolet cure process; and a second dielectric material 242 that is deposited by the second instance of the flowable chemical vapor deposition process and is cured by the second instance of the ultraviolet cure process fills the gaps, and comprises concave surface segments at levels of the gaps. In one embodiment, the method may further include: forming a vertically alternating sequence of the semiconductor nanowires 10 and sacrificial nanowires 20 over a substrate 6, wherein the sacrificial gate electrode 32 is formed over the vertically alternating sequence; isotropically etching an entirety of the sacrificial nanowires 20 selective to the semiconductor nanowires 10, whereby the gaps 19 are formed in volumes from which the sacrificial nanowires 20 are removed; and performing a conformal dielectric material deposition process that forms a conformal dielectric liner 30 on physically exposed surfaces of the semiconductor nanowires 10 prior to performing the at least two iterations of the sequence of processing steps. In one embodiment, the semiconductor nanowires 10 comprise portions of a single crystalline semiconductor material; and the method comprises performing a selective epitaxy process that grows a doped epitaxial semiconductor material from physically exposed surfaces of the semiconductor nanowires 10, whereby a pair of epitaxial source/drain regions 52 laterally spaced from each other by the dielectric spacer structures is formed.

According to an aspect of the present disclosure, multiple iterations of a sequence of processing steps may be used to fill gaps 19 between vertically neighboring pairs of semiconductor nanowires 10. Each iteration of the sequence of processing steps includes a respective flowable chemical vapor deposition process that deposits a respective dielectric material, and a respective ultraviolet cure process that irradiates ultraviolet radiation to the respective dielectric material. The use of the multiple instances of the flowable chemical vapor deposition process and the multiple instances of the ultraviolet cure process enhances the overall fill quality of the deposited dielectric materials to provide a seamless dielectric fill. Embodiments of the present disclosure provide uniform and voidless gap fill, and improved mechanical stability for the dielectric spacer structures 24. The dielectric spacer structures 24 are formed with planar vertical sidewalls that are perpendicular to the first horizontal direction hd1, Thus, use of the multiple instances of the flowable chemical vapor deposition process and multiple instances of the ultraviolet cure process provides formation of multiple semiconductor channels having a uniform channel length.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph of in different paragraphs, a Markush group including a listing of the two or more elements may be also impliedly disclosed in some embodiments. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming semiconductor nanowires over a substrate, wherein the semiconductor nanowires and the substrate are vertically spaced from one another by gaps, and wherein the semiconductor nanowires are suspended over the substrate by a support structure;
performing at least two iterations of a sequence of processing steps that includes a flowable chemical vapor deposition process that deposits a respective dielectric material and an ultraviolet cure process that irradiates ultraviolet radiation to the respective dielectric material; and
forming dielectric spacer structures having a lesser lateral extent than the semiconductor nanowires by isotropically etching the dielectric materials deposited by instances of the flowable chemical vapor deposition process and densified by instances of the ultraviolet cure process.

2. The method of claim 1, wherein the dielectric materials deposited by the instances of the flowable chemical vapor deposition process fill a volume of each of the gaps.

3. The method of claim 1, wherein the at least two iterations of the sequence comprises:
a first iteration of the sequence that includes a first instance of the flowable chemical vapor deposition process and a first instance of the ultraviolet cure process; and
a second iteration of the sequence that includes a second instance of the flowable chemical vapor deposition process and a second instance of the ultraviolet cure process.

4. The method of claim 3, wherein the first instance of the flowable chemical vapor deposition process deposits a first dielectric material on horizontal surfaces of the semiconductor nanowires such that the first dielectric material has a greater thickness at a center portion of each of the horizontal surfaces of the semiconductor nanowires than peripheral portions of each of the horizontal surfaces of the semiconductor nanowires.

5. The method of claim 4, wherein a second dielectric material that is deposited by the second instance of the flowable chemical vapor deposition process and is cured by the second instance of the ultraviolet cure process fills the gaps, and comprises a contoured vertically-extending surface that comprises concave surface segments at levels of the gaps.

6. The method of claim 5, wherein:
the at least two iterations of the sequence comprises a third iteration of the sequence that includes a third instance of the flowable chemical vapor deposition process and a third instance of the ultraviolet cure process; and
a third dielectric material that is deposited by the third instance of the flowable chemical vapor deposition process and is cured by the third instance of the ultraviolet cure process comprises a planar vertically-extending surface that vertically extends continuously through each level of the semiconductor nanowires and through each level of the gaps.

7. The method of claim 3, wherein:
each horizontally-extending portion of a first dielectric material that is deposited by the first instance of the flowable chemical vapor deposition process has a physically exposed surface after the first instance of the flowable chemical vapor deposition process; and
the physically exposed surfaces has a convex vertical cross-sectional profile in a vertical cross-sectional view along a vertical plane that is parallel to a lengthwise direction of the semiconductor nanowires.

8. The method of claim 3, wherein a first dielectric material that is deposited by the first instance of the flowable chemical vapor deposition process has a greater thickness on a center portion of a horizontally-extending surface of one of the semiconductor nanowires than on a sidewall of said one of the semiconductor nanowires.

9. The method of claim 3, wherein a first dielectric material that is deposited by the first instance of the flowable chemical vapor deposition process and is cured by the first instance of the ultraviolet cure process fills the gaps, and comprises a contoured vertically-extending surface that comprises concave surface segments at levels of the gaps.

10. The method of claim 9, wherein a second dielectric material that is deposited by the second instance of the flowable chemical vapor deposition process and is cured by the second instance of the ultraviolet cure process comprises a planar vertically-extending surface that vertically extends continuously through each level of the semiconductor nanowires and through each level of the gaps.

11. A method of forming a field effect transistor, comprising:
forming a vertically alternating sequence of semiconductor nanowires and sacrificial nanowires over a substrate;
forming a sacrificial gate electrode over the vertically alternating sequence;
forming gaps between the semiconductor nanowires by removing an entirety of the sacrificial nanowires;
performing at least two iterations of a sequence of processing steps that includes a flowable chemical vapor deposition process that deposits a respective dielectric material and an ultraviolet cure process that irradiates ultraviolet radiation to the respective dielectric material;
forming dielectric spacer structures having a lesser lateral extent than the semiconductor nanowires by performing a selective isotropic etch process that isotropically etches the dielectric materials deposited by instances of the flowable chemical vapor deposition process and densified by instances of the ultraviolet cure process selective to the semiconductor nanowires; and
replacing a combination comprising the sacrificial gate electrode and the dielectric spacer structures with a combination of a gate dielectric and a gate electrode.

12. The method of claim 11, wherein:
the at least two iterations of the sequence comprises a first iteration of the sequence that includes a first instance of the flowable chemical vapor deposition process and a first instance of the ultraviolet cure process; and
the first instance of the flowable chemical vapor deposition process deposits a first dielectric material on horizontal surfaces of the semiconductor nanowires with a non-uniform thickness distribution such that the first dielectric material has a greater thickness at a center portion of each of the horizontal surfaces of the semiconductor nanowires than peripheral portions of each of the horizontal surfaces of the semiconductor nanowires.

13. The method of claim 12, wherein:
the at least two iterations of the sequence comprises a second iteration of the sequence that includes a second instance of the flowable chemical vapor deposition process and a second instance of the ultraviolet cure process; and
a second dielectric material that is deposited by the second instance of the flowable chemical vapor deposition process and is cured by the second instance of the ultraviolet cure process fills the gaps, and comprises a contoured vertically-extending surface that comprises concave surface segments at levels of the gaps.

14. The method of claim 11, wherein:
the selective isotropic etch process etches each of the dielectric materials at a same etch rate; and
sidewalls of the dielectric spacers are formed within a pair of parallel planar vertical planes upon termination of the selective isotropic etch process.

15. The method of claim 1, further comprising performing a selective semiconductor deposition process that grows a semiconductor material portion comprising a semiconductor material from physically exposed surfaces of the semiconductor nanowires while suppressing growth of the semiconductor material from surfaces of the of the dielectric spacer structures, whereby the volumes of the gaps are filled with a combination of the dielectric spacer structures and the semiconductor material portion.

16. A method of forming a gate-all-around field effect transistor, comprising:
forming semiconductor nanowires over a substrate, wherein the semiconductor nanowires and the substrate are vertically spaced from one another by gaps, and wherein the semiconductor nanowires are suspended over the substrate by a sacrificial gate electrode;
performing at least two iterations of a sequence of processing steps that includes a flowable chemical vapor deposition process that deposits a respective dielectric material and an ultraviolet cure process that irradiates ultraviolet radiation to the respective dielectric material;
forming dielectric spacer structures having a lesser lateral extent than the semiconductor nanowires by performing a selective isotropic etch process that isotropically etches the dielectric materials deposited by instances of the flowable chemical vapor deposition process and densified by instances of the ultraviolet cure process selective to the semiconductor nanowires;
forming source/drain regions on physically exposed surfaces of the semiconductor nanowires; and
replacing a combination of the sacrificial gate electrode and the dielectric spacer structures with a combination of a gate dielectric and a gate electrode.

17. The method of claim 16, wherein:
the at least two iterations of the sequence comprises a first iteration of the sequence that includes a first instance of the flowable chemical vapor deposition process and a first instance of the ultraviolet cure process;
each horizontally-extending portion of a first dielectric material that is deposited by the first instance of the flowable chemical vapor deposition process has a physically exposed surface after the first instance of the flowable chemical vapor deposition process; and
the physically exposed surfaces has a convex vertical cross-sectional profile in a vertical cross-sectional view along a vertical plane that is parallel to a lengthwise direction of the semiconductor nanowires.

18. The method of claim 17, wherein:
the at least two iterations of the sequence comprises a second iteration of the sequence that includes a second instance of the flowable chemical vapor deposition process and a second instance of the ultraviolet cure process; and
a second dielectric material that is deposited by the second instance of the flowable chemical vapor deposition process and is cured by the second instance of the ultraviolet cure process fills the gaps, and comprises concave surface segments at levels of the gaps.

19. The method of claim 16, further comprising:
forming a vertically alternating sequence of the semiconductor nanowires and sacrificial nanowires over a substrate, wherein the sacrificial gate electrode is formed over the vertically alternating sequence;
isotropically etching an entirety of the sacrificial nanowires selective to the semiconductor nanowires, whereby the gaps are formed in volumes from which the sacrificial nanowires are removed; and
performing a conformal dielectric material deposition process that forms a conformal dielectric liner on physically exposed surfaces of the semiconductor nanowires prior to performing the at least two iterations of the sequence of processing steps.

20. The method of claim 16, wherein:
the semiconductor nanowires comprise portions of a single crystalline semiconductor material; and
the method comprises performing a selective epitaxy process that grows a doped epitaxial semiconductor material from physically exposed surfaces of the semiconductor nanowires, whereby a pair of epitaxial source/drain regions laterally spaced from each other by the dielectric spacer structures is formed.
